(19) United States
(12) Patent Application Publication
(10) Pub. No.: US 2024/0149390 A1
(43) Pub. Date: May 9, 2024

(54) POLISHING PAD AND METHOD FOR MANUFACTURING POLISHING PAD

(71) Applicant: FUJIBO HOLDINGS, INC., Tokyo (JP)

(72) Inventors: Yoshihide KAWAMURA, Ehime (JP); Teppei TATENO, Ehime (JP); Hiroshi KURIHARA, Ehime (JP); Satsuki YAMAGUCHI, Ehime (JP); Yamato TAKAMIZAWA, Ehime (JP); Keisuke OCHI, Ehime (JP); Tetsuaki KAWASAKI, Ehime (JP)

(73) Assignee: FUJIBO HOLDINGS, INC., Tokyo (JP)

(21) Appl. No.: 18/278,405

(22) PCT Filed: Mar. 18, 2022
(86) PCT No.: PCT/JP2022/012709

§ 371 Date: Aug. 22, 2023

(30) Foreign Application Priority Data
Mar. 30, 2021 (JP) 2021-056761
Sep. 29, 2021 (JP) 2021-159887
Sep. 29, 2021 (JP) 2021-159888

(51) Int. Cl. B24B 37/22

(52) U.S. Cl. CPC B24B 37/22

(57) ABSTRACT

Provided is a polishing pad comprising a polishing layer made of a polyurethane resin foam containing an isocyanate-terminated prepolymer, and a curing agent, wherein the ratio (NC80/NC40) of a weight proportion (NC80) of an amorphous phase content in the polishing layer measured at 80° C. by a pulsed NMR method to a weight proportion (NC40) of the amorphous phase content in the polishing layer measured at 40° C. by the pulsed NMR method is between 1.5 and 2.5.

### TECHNICAL FIELD

The present invention relates to a polishing pad. The polishing pad of the present invention is used to polish optical materials, semiconductor devices, glass substrates for hard disks and the like and is suitably used to polish, particularly, devices having an oxide layer, a metal layer or the like formed on a semiconductor wafer.

### BACKGROUND ART

As a polishing method for flattening the surfaces of optical materials, semiconductor wafers, semiconductor devices and hard disk substrates, a chemical mechanical polishing (CMP) method has been ordinarily used.

The CMP method will be described using FIG. 1. As shown in FIG. 1, a polishing device 1 configured to perform the CMP method is provided with a polishing pad 3, and the polishing pad 3 includes a polishing layer 4 that is a layer that comes into contact with an item to be polished 8 held in a retainer ring (not shown in FIG. 1) configured to hold a holding surface plate 16 and the item to be polished 8 so as not to deviate from each other and performs polishing and a cushion layer 6 that supports the polishing layer 4. The polishing pad 3 is driven to rotate in a state where the item to be polished 8 is pressed and polishes the item to be polished 8. At that time, a slurry 9 is supplied between the polishing pad 3 and the item to be polished 8. The slurry 9 is a mixture (dispersion) of water and a variety of chemical components or fine hard abrasive grains and enhances the polishing effect due to a relative movement between the item to be polished 8 and the chemical components or the abrasive grains in the slurry that are made to flow. The slurry 9 is supplied to and discharged from a polishing surface through grooves or holes.

Incidentally, as a material of the polishing layer that is used to polish semiconductor devices, a hard polyurethane material that is obtained by reacting a prepolymer containing an isocyanate component (toluene diisocyanate (TDI) or the like) and a high-molecular-weight polyol (poly(oxytetramethylene) glycol (PTMG) or the like) and a diamine-based curing agent (4,4′-methylene-bis(2-chloroaniline) (MOCA) or the like) is used. This hard polyurethane material is composed of soft segments that are formed of a high-molecular-weight polyol and hard segments that are formed of a urethane bond or a urea bond. Recently, in association with cable miniaturization in semiconductor devices, in conventional polishing layers or polishing pads, there are cases where the polishing rate or the defect performance (scratches or the like) is not sufficient, and additional studies are underway.

Patent Literature 1 discloses a polishing pad capable of stable polishing in which the use of a polishing layer in which the content proportion of a crystalline phase (S phase) as measured and obtained by pulse NMR exceeds 70% decreases a change in hardness due to heat, which consequently enables sufficient polishing and makes it difficult for a mark to be formed.

However, as a result of studying Patent Literature 1, it was found that, simply under the condition where the crystalline phase exceeds 70% at normal temperature, scratches are likely to be generated. This is because, when a foreign matter has been incorporated during polishing, there are cases where the foreign matter increases the temperature, whereby the abundance proportions of the crystalline phase, an intermediate phase and an amorphous phase change and the characteristics of the polishing layer change.

In addition, from the viewpoint of durability, polishing pads are preferably hard; however, when polishing pads are too hard, the polishing pads do not have a characteristic for eliminating unevenness present on items to be polished (step performance), and there is also a disadvantage in that steps are not completely eliminated even when polishing continues.

Regarding the hard polyurethane material, furthermore, studies are underway to use polyols other than PTMG as the high-molecular-weight polyol in order to eliminate insufficient polishing rates or defect performance.

Patent Literature 2 discloses a polishing pad in which polypropylene glycol (PPG) is used as the high-molecular-weight polyol in the prepolymer, whereby the step elimination performance is high and the number of scratches is small.

In addition, Patent Literature 3 discloses a polishing pad in which a mixture of PPG and PTMG is used as the high-molecular-weight polyol in the prepolymer, whereby the defect rate has been reduced.

However, the polishing pad described in Patent Literature 2 had a problem in that the wear resistance of a polishing layer was poor, the life of the polishing pad was short and the polishing rate was not sufficient. In addition, the polishing pad described in Patent Literature 3 contained PTMG and thus had a problem in that the defect performance was not sufficient.

In addition, normally, in order to realize high polishing rates, there was a need to make polishing pads highly hard, but highly hard polishing pads had poor defect performance (scratch performance), and the polishing rate and the defect performance had a trade-off relationship.

### CITATION LIST

### Patent Literature

### [Patent Literature 1]

Domestic Re-publication of PCT International Application No. 2016/158348

### [Patent Literature 2]

Japanese Patent Laid-Open No. 2020-157415

### [Patent Literature 3]

Japanese Patent Laid-Open No. 2011-040737

### SUMMARY OF INVENTION

### Technical Problem

The present invention has been made in consideration of the above-described problems, and an objective of the present invention is to provide a polishing pad being excellent in terms of step elimination performance, realizing a high polishing rate, being excellent in terms of defect performance and, furthermore, being excellent in terms of wear resistance.

The present inventors studied the proportions of a crystalline phase, an intermediate phase and an amorphous phase in a polishing layer and found that, in a case where the content proportion by weight of the amorphous phase at 40° C. and the content proportion by weight of the amorphous phase at 80° C. are within predetermined ranges, it is possible to obtain a polishing pad including a polishing layer that does not easily allow a mark to be formed and is excellent in terms of step elimination performance.

In addition, it was found that, when a specific polyol is used as a polyol that is a material used for the polishing layer in the polishing pad, it is possible to produce a polishing pad that realizes a high polishing rate, is excellent in terms of defect performance and is, furthermore, excellent in terms of wear resistance.

That is, the present invention includes the followings.

### Solution to Problem

[1] A polishing pad having a polishing layer composed of a polyurethane resin foam derived from an isocyanate-terminated prepolymer and a curing agent,
in which a ratio (NC80/NC40) of a content proportion by weight (NC80) of an amorphous phase in the polishing layer as measured by pulse NMR at 80° C. to a content proportion by weight (NC40) of the amorphous phase in the polishing layer as measured by pulse NMR at 40° C. is 1.5-2.5.
[2] The polishing pad according to [1], in which a numerical value that is obtained from Expression (1) below in which content proportions by weight of the amorphous phase and a crystalline phase in the polishing layer as measured by pulse NMR at 40° C. and 80° C. are used:

$$\begin{matrix}[ Math . 1 ] & \\ \frac{\begin{matrix}Content proportion by weight of amorphous \\ phase measured at 80 ° C . ( NC 80 )\end{matrix}}{\begin{matrix}Content proportion by weight of amorphous \\ phase measured at 40 ° C . ( NC 40 )\end{matrix}} - \frac{\begin{matrix}Content proportion by weight of crystalline \\ phase measured at 80 ° C . ( CC 80 )\end{matrix}}{\begin{matrix}Content proportion by weight of crystalline \\ phase measured at 40 ° C ( CC 40 )\end{matrix}} & Expression ( 1 )\end{matrix}$$

is 1.20-1.50.
[3] The polishing pad according to [1] or [2], in which the NC40 is 10-20 weight %.
[4] The polishing pad according to any one of [1] to [3], in which the NC80 is 25-35 weight %.
[5] The polishing pad according to any one of [1] to [4], in which the polishing layer contains a polypropylene glycol and a polyether polycarbonate diol.
[6] The polishing pad according to [5], in which a proportion of the polyether polycarbonate diol with respect to a total of the polypropylene glycol and the polyether polycarbonate diol is less than 80%.
[7] A polishing pad having a polishing layer composed of a polyurethane resin foam derived from an isocyanate-terminated prepolymer and a curing agent,
in which a numerical value that is obtained from Expression (2) below in which content proportions by weight of an amorphous phase and a crystalline phase in the polishing layer as measured by pulse NMR at 40° C. and 80° C. are used:

$$\begin{matrix}[ Math . 2 ] & \\ \frac{\begin{matrix}Content proportion by weight of amorphous \\ phase measured at 80 ° C . ( NC 80 )\end{matrix}}{\begin{matrix}Content proportion by weight of crystalline \\ phase measured at 40 ° C . ( CC 40 )\end{matrix}} - \frac{\begin{matrix}Content proportion by weight of amorphous \\ phase measured at 80 ° C . ( NC 80 )\end{matrix}}{\begin{matrix}Content proportion by weight of crystalline \\ phase measured at 40 ° C . ( CC 40 )\end{matrix}} & Expression ( 2 )\end{matrix}$$

is 0.70-1.30.
[8] The polishing pad according to [7], in which a difference between a maximum value and a minimum value of tan δ as obtained by measuring the polishing layer by a dynamic mechanical analysis at 40° C.-80° C. is 0.030 or less.
[9] The polishing pad according to [7] or [8], in which the NC40 is 10-20 weight %.
[10] The polishing pad according to any one of [7] to [9], in which the NC80 is 25-35 weight %.
[11] The polishing pad according to any one of [7] to [10], in which the polishing layer contains a polypropylene glycol and a polyether polycarbonate diol.
[12] The polishing pad according to [11], in which a proportion of the polyether polycarbonate diol with respect to a total of the polypropylene glycol and the polyether polycarbonate diol is less than 80%.
[13] A polishing pad having a polishing layer composed of a polyurethane resin foam derived from an isocyanate-terminated prepolymer and a curing agent,
in which the isocyanate-terminated prepolymer includes a polyisocyanate compound-derived configuration unit and a high-molecular-weight polyol-derived configuration unit,
the high-molecular-weight polyol-derived configuration unit is composed of at least a polypropylene glycol configuration unit and a polyether polycarbonate diol configuration unit, and
there is less than 80 weight % of the polypropylene glycol configuration unit with respect to the high-molecular-weight polyol-derived configuration unit.
[14] The polishing pad according to [13], in which there is 30-70 weight % of the polypropylene glycol configuration unit with respect to the high-molecular-weight polyol-derived configuration unit.
[15] The polishing pad according to or [14], in which the polyether polycarbonate diol configuration unit is derived from a polyether polycarbonate diol having a number-average molecular weight of 600-2500.
[16] A method for manufacturing a polishing pad having a polishing layer composed of a polyurethane resin foam, the method including
a step of reacting a polyisocyanate compound and a high-molecular-weight polyol containing at least a polypropylene glycol and a polyether polycarbonate diol to obtain an isocyanate-terminated prepolymer,
a step of reacting the isocyanate-terminated prepolymer and a curing agent to obtain the polyurethane resin foam, and
a step of molding the polyurethane resin foam into a shape of the polishing layer,
in which there is less than 80 weight % of the polypropylene glycol with respect to a total amount of the high-molecular-weight polyol.

### Advantageous Effects of Invention

The polishing pad of the present invention has excellent defect performance and has excellent step elimination performance and polishing rate.

In addition, according to the polishing pad of the present invention, the high-molecular-weight polyol containing a polypropylene glycol and a polyether polycarbonate diol is used as the material of the polishing layer, whereby it is possible to obtain a polishing pad that realizes a high polishing rate, is excellent in terms of defect performance and is, furthermore, excellent in terms of wear resistance.

### BRIEF DESCRIPTION OF DRAWINGS

FIG. 1 is a pattern diagram showing a state where polishing is performed using a polishing pad.

FIG. 2 is a pattern diagram of the polishing pad and a cross-sectional view of the polishing pad.

FIG. 3 is a view for describing step elimination performance.

FIG. 4 shows the results of step elimination performance tests of examples and a comparative example (cases where a wiring having a Cu wiring width of 120 μm is used as an item to be polished).

FIG. 5 shows the results of step elimination performance tests of the examples and the comparative example (cases where a wiring in which the width of an insulating film was 100 μm with respect to a Cu wiring width of 100 μm is used as an item to be polished).

FIG. 6 shows the results of step elimination performance tests of the examples and the comparative example (cases where a wiring in which the width of an insulating film was 50 μm with respect to a Cu wiring width of 50 μm is used as an item to be polished).

FIG. 7 shows the results of step elimination performance tests of the examples and the comparative example (cases where a wiring in which the width of an insulating film was 10 μm with respect to a Cu wiring width of 10 μm is used as an item to be polished).

FIG. 8 shows the results of the defect performance evaluation tests of the example and the comparative example.

FIG. 9 is the result of tan δ obtained in Example 6.

FIG. 10 is the result of tan δ obtained in Comparative Example 2.

FIG. 11 is graphs showing the step elimination performance of the examples and the comparative example (cases where a wiring in which the width of an insulating film was 100 μm with respect to a Cu wiring width of 100 μm is used as an item to be polished).

FIG. 12 is graphs showing the step elimination performance of the examples and the comparative example (cases where a wiring in which the width of an insulating film was 50 μm with respect to a Cu wiring width of 50 μm is used as an item to be polished).

FIG. 13 is a graph showing changes in the wear amounts (thicknesses) of polishing pads of an example and a comparative example.

FIG. 14 is graphs showing the evaluation results of the polishing rates of polishing pads of examples and comparative examples.

FIG. 15 is the polishing test results of the defect performance of the examples and the comparative examples.

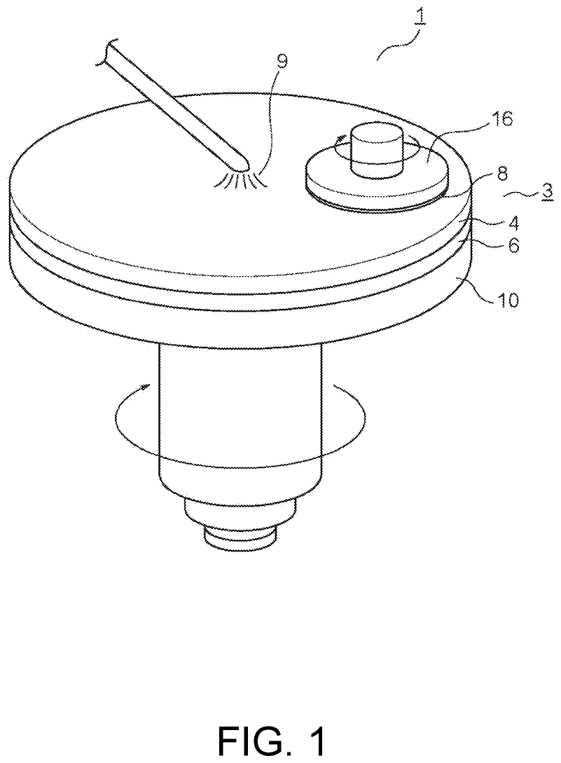

### DESCRIPTION OF EMBODIMENTS

Hereinafter, an embodiment of an invention will be described, but the present invention is not limited to the embodiment of the invention.

### <<Polishing Pad>>

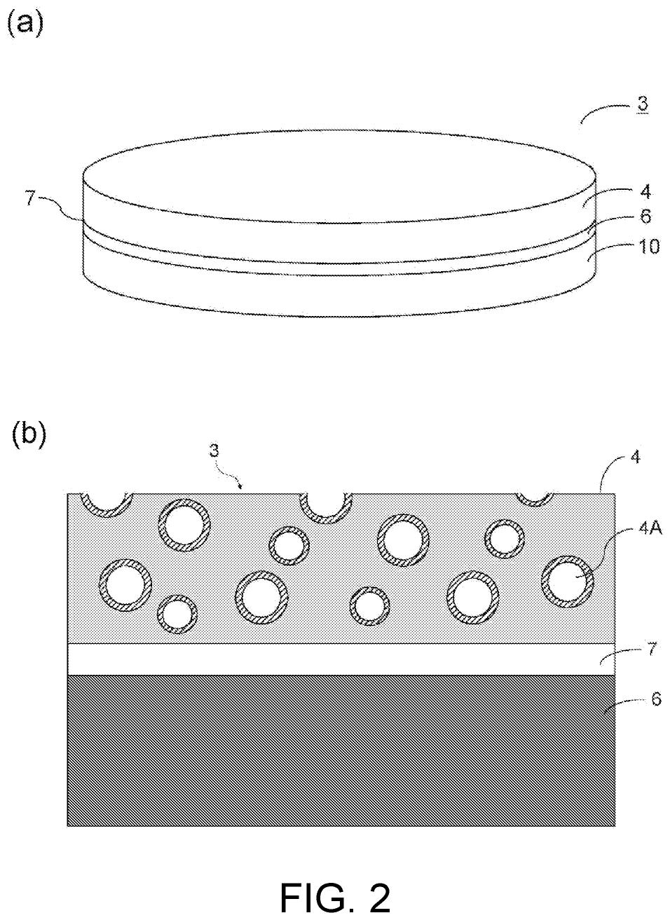

The structure of a polishing pad 3 will be described using FIG. 2. The polishing pad 3 includes a polishing layer 4 and a cushion layer 6 as shown in FIG. 2. The shape of the polishing pad 3 is preferably a disc shape, but is not particularly limited, and the size (diameter) can also be determined as appropriate depending on the size or the like of a polishing device 1 including the polishing pad 3 and can be set to, for example, approximately 10 cm to 2 m in diameter.

In the polishing pad 3 of the present invention, it is preferable that the polishing layer 4 adhere to the cushion layer 6 through an adhesive layer 7 as shown in FIG. 2.

The polishing pad 3 is pasted to a polishing surface plate 10 of the polishing device 1 with double-sided tape or the like provided on the cushion layer 6. The polishing pad 3 is driven to rotate by the polishing device 1 in a state where the item to be polished 8 is pressed and polishes the item to be polished 8.

### <Polishing Layer>

### (Configuration)

The polishing pad 3 includes the polishing layer 4 that is a layer for polishing the item to be polished 8. A material that configures the polishing layer 4 is a polyurethane resin foam. The material, manufacturing method and the like of the polyurethane resin foam will be described below.

The size (diameter) of the polishing layer 4 is the same as that of the polishing pad 3 and can be set to approximately 10 cm to 2 m in diameter, and the thickness of the polishing layer 4 can be set to normally approximately 1-5 mm.

The polishing layer 4 is rotated together with the polishing surface plate 10 of the polishing device 1 and polishes the item to be polished 8 by causing chemical components or abrasive grains that are contained in a slurry 9 to relatively move together with the item to be polished 8 while the slurry 9 is made to flow thereon.

The polishing layer 4 is rotated together with the polishing surface plate 10 of the polishing device 1 and polishes the item to be polished 8 by causing chemical components or abrasive grains that are contained in a slurry 9 to relatively move together with the item to be polished 8 while the slurry 9 is made to flow thereon.

The polishing layer 4 may include hollow microspheres 4A in a dispersed state as shown in FIG. 2. In a case where the hollow microspheres 4A are included in a dispersed state, once the polishing layer 4 is worn, the hollow microspheres 4A are exposed on a polishing surface, fine voids are generated on the polishing surface, and the slurry is held in these fine voids, whereby it is possible to further progress the polishing of the item to be polished 8.

In addition, the polishing layer 4 preferably has been dry-molded.

### (Grooving)

On the surface of the polishing layer 4 of the present invention on the item to be polished 8 side, it is preferable to provide grooving as necessary. Grooves are not particularly limited and may be any of slurry discharge grooves that communicate with the circumference of the polishing layer 4 and slurry holding grooves that do not communicate with the circumference of the polishing layer 4, and both the slurry discharge grooves and the slurry holding grooves may be provided. Examples of the slurry discharge grooves include lattice grooves, radial grooves and the like, examples of the slurry holding grooves include concentric circular grooves, perforations (through-holes) and the like, and it is also possible to combine these.

(Shore D hardness)

The shore D hardness of the polishing layer 4 of the present invention is not particularly limited, but is, for example, 20-100, preferably 30-80 and more preferably 40-70. In a case where the shore D hardness is small, it becomes difficult to flatten fine unevenness in low-pressure polishing processes. When the shore D hardness is too high, there is a possibility that the polishing layer may be strongly rubbed against the item to be polished 8 and scratches may be generated on a processed surface of the item to be polished 8.

In the polishing pad 3 of the present invention, bubbles are included in a polyurethane resin compact using the hollow microspheres 4. The hollow microsphere means a microsphere having a void. The shape of the hollow microsphere 4A may be a spherical shape, an elliptical shape or a shape close thereto. Additional description of the hollow microspheres will be described in the “manufacturing method” section.

### (Crystalline Phase, Intermediate Phase and Amorphous Phase)

In the polishing layer of the polishing pad of a certain aspect of the present invention, the ratio (expressed as NC80/NC40 in some cases) of the content proportion by weight (NC80) of the amorphous phase in the polishing layer as measured at 80° C. to the content proportion by weight (NC40) of the amorphous phase as measured at 40° C. is 1.50-2.50. In the case of being mentioned in the present specification, the content proportion is a proportion calculated based on weight (weight %).

In the present specification, there will be cases where the content proportion by weight of the amorphous phase as measured at 40° C. is abbreviated as NC40 and the content proportion by weight of the amorphous phase as measured at 80° C. is abbreviated as NC80. In addition, while described below, there will be cases where the content proportion by weight of the crystalline phase as measured at 40° C. is abbreviated as CC40 and the content proportion by weight of the crystalline phase as measured at 80° C. is abbreviated as CC80.

Ordinarily, when polishing is performed, the temperature of the polishing pad increases due to the polishing. When the temperature has increased, if the hardness is high, scratches are likely to be generated, and there is a concern that the defect performance may deteriorate. That is, when NC80/NC40 is less than 1.50, scratches are likely to be generated, and there is a concern that the defect performance may deteriorate. On the other hand, when NC80/NC40 exceeds 2.50, the proportion of the soft segments increases when the temperature has increased, whereby the polishing pad becomes soft, and the polishing rate deteriorates, which is not preferable.

The lower limit of NC80/NC40 is preferably 1.60 or more and more preferably 1.70 or more. On the other hand, the upper limit is preferably 2.40 or less and more preferably 2.30 or less.

Furthermore, in the polishing layer, the value as calculated from Expression (1) below preferably satisfies 1.20-1.50.

$$\begin{matrix}[ Math . 3 ] & \\ \frac{\begin{matrix}Content proportion by weight of amorphous \\ phase measured at 80 ° C . ( NC 80 )\end{matrix}}{\begin{matrix}Content proportion by weight of amorphous \\ phase measured at 40 ° C . ( NC 40 )\end{matrix}} - \frac{\begin{matrix}Content proportion by weight of crystalline \\ phase measured at 80 ° C . ( CC 80 )\end{matrix}}{\begin{matrix}Content proportion by weight of crystalline \\ phase measured at 40 ° C . ( CC 40 )\end{matrix}} & Expression ( 1 )\end{matrix}$$

What Expression (1) means is that the proportion of the amorphous phase increasing by a change from 40° C. to 80° C. is larger than the proportion of the crystalline phase increasing by the change from 40° C. to 80° C. and the magnitude satisfies 1.20-1.50. When the magnitude is less than 1.20, as the temperature increases, the balance between the proportion of the amorphous phase and the proportion of the crystalline phase becomes poorer, and there is a concern that the defect performance, particularly scratches, may be adversely affected, and, when the magnitude exceeds 1.50, as the temperature increases, the proportion of the amorphous phase increases, and the polishing layer becomes softer, whereby there are cases where the polishing rate deteriorates. The lower limit of Expression (1) is more preferably 1.22 or more and still more preferably 1.25 or more. In addition, the upper limit is more preferably 1.48 or less and still more preferably 1.45 or less.

Furthermore, NC40 of the polishing layer is preferably 10-20 weight %. When NC40 is 10-20 weight %, an excellent polishing rate can be obtained, which is preferable.

In addition, NC80 of the polishing layer is preferably 25-35 weight %. When NC80 is 25-35 weight %, since the soft segments has a certain amount of the amorphous phase when the temperature has increased, excellent defect performance is exhibited while an excellent polishing rate is obtained.

In one aspect of the present invention, in the polishing layer of the polishing pad, a value as obtained from Expression (2) where the content proportion by weight (NC40) of the amorphous phase as measured at 40° C., the content proportion by weight (NC80) of the amorphous phase as measured at 80° C., the content proportion by weight (CC40) of the crystalline phase as measured at 40° C. and the content proportion by weight (CC80) of the crystalline phase as measured at 80° C. are used is preferably 0.70-1.30.

$$\begin{matrix}[ Math . 4 ] & \\ \frac{\begin{matrix}Content proportion by weight of amorphous \\ phase measured at 80 ° C . ( NC 80 )\end{matrix}}{\begin{matrix}Content proportion by weight of crystalline \\ phase measured at 80 ° C . ( CC 80 )\end{matrix}} - \frac{\begin{matrix}Content proportion by weight of amorphous \\ phase measured at 40 ° C . ( NC 40 )\end{matrix}}{\begin{matrix}Content proportion by weight of crystalline \\ phase measured at 40 ° C . ( CC 40 )\end{matrix}} & Expression ( 2 )\end{matrix}$$

What Expression (2) means is that the ratios between the amorphous phase and the crystalline phase at 40° C. and 80° C. are obtained, respectively, the ratio at 80° C. is larger than the ratio at 40° C., and the magnitude satisfies 0.70-1.30.

Polishing is performed at approximately 40° C., but there are cases where the temperature of the polishing pad increases to approximately 80° C. due to friction as polishing progresses.

In a case where the value of Expression (2) is less than 0.7 and more than 1.30, the balance between the amorphous phase and the crystalline phase deteriorates in association with the temperature change, and the step elimination performance and the wear resistance deteriorate.

The lower limit of the value that is obtained from Expression (2) is preferably 0.80 or more and more preferably 0.90 or more. The upper limit of the value that is obtained from Expression (2) is preferably 1.29 or less and more preferably 1.28 or less.

NC40 of the polishing layer is preferably 10-20 weight %. When NC40 is 10-20 weight %, the polishing pad obtains appropriate hardness, and the step elimination performance becomes favorable, which is preferable.

In addition, NC80 of the polishing layer is preferably 25-35 weight %. When NC80 is 25.0 weight % or more and 35 weight % or less, since soft segments has a certain amount of the amorphous phase, excellent step elimination performance and wear resistance are exhibited.

In addition, the proportions of the crystalline phase, an intermediate phase and the amorphous phase in the polishing layer are measured by pulse NMR. In pulse NMR measurement, a foamed polyurethane is classified into each of a phase for which the spin-spin relaxation time is shorter than 0.03 ms (short phase) (S phase), a phase for which the spin-spin relaxation time is 0.03 ms or longer and shorter than 0.2 ms (middle phase) (M phase) and a phase for which the spin-spin relaxation time is 0.2 ms or longer (long phase) (L phase), and the content proportion by weight of each phase is obtained. Regarding the content proportions by weight of the S phase, the M phase and the L phase, for example, in the pulse NMR measurement, mainly the crystalline phase is observed as the S phase, mainly the amorphous phase is observed as the L phase, and mainly the intermediate phase is observed as the M phase in the pulse NMR measurement. In addition, in the pulse NMR measurement, mainly the hard segment is observed as the S phase, and mainly the soft segment is observed as the L phase.

The spin-spin relaxation time can be obtained by performing measurement by the solid echo method using, for example, “JNM-MU25” manufactured by JEOL, Ltd.

### <Tan δ>

In the polishing layer of the present invention, regarding tan δ that is the ratio between the storage modulus E′ and the loss modulus E″ when a dynamic mechanical analysis has been performed on the entire polishing layer in a tensile mode at a frequency of 10 rad/sec, a temperature of 20-100° C., the difference between the maximum value (tan δₘₐₓ) and the minimum value (tan δₘᵢₙ) within a range of 40-80° C. is preferably 0.030 or less.

tan δ is the ratio (E″/E′) of E″ (loss modulus) to E′ (storage modulus). When the temperature of the polishing layer increases due to heat energy such as polishing heat, the proportion of the amorphous phase in the polishing layer becomes large, E″ (loss modulus) is expected to become large with respect to E′ (storage modulus), and, in such a case, the value of tan δ is expected to become large.

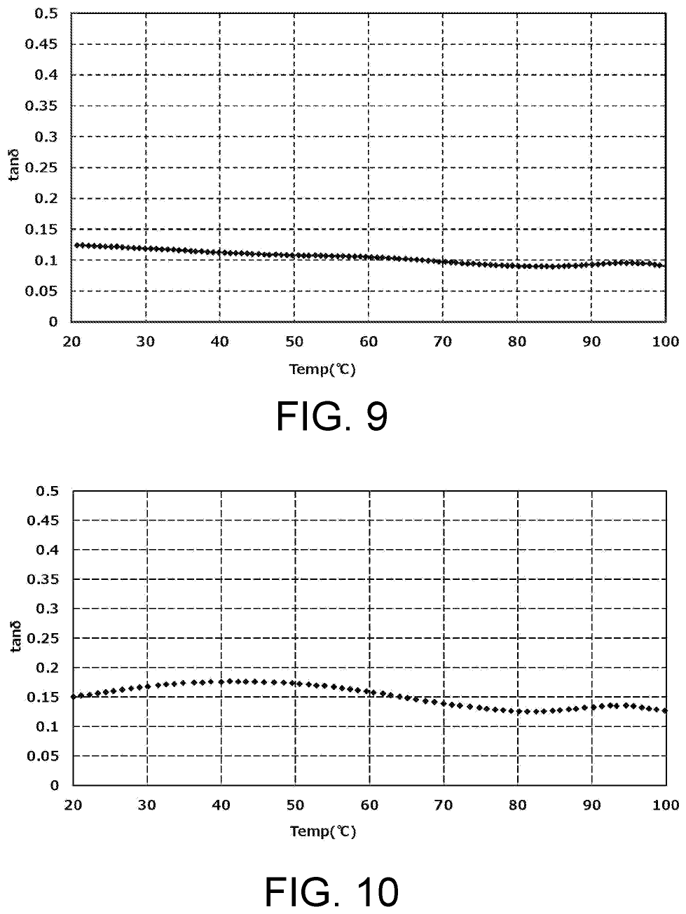

However, tan δ of the polishing layer that is used in the polishing pad of the present invention tends to decrease slightly as the temperature increases from 40° C. to 80° C. at 40-80° C. (for example, refer to FIG. 9). In addition, the decrease rate is extremely small, and the difference between the maximum value (tan 6 max) and the minimum value (tan δₘᵢₙ) of tan δ at 40-80° C. is 0.030 or less. When the difference between the maximum value (tan δₘₐₓ) and the minimum value (tan δₘᵢₙ) of tan δ is 0.030 or less across a range from 40° C. to 80° C., there is a tendency that excellent step elimination performance can be maintained even at such a temperature during polishing as 80° C.

tan δ is measured from the polishing layer in a tensile mode by a dynamic mechanical analysis (DMA). The dynamic mechanical analysis (DMA) is a method for measuring the dynamic properties of a sample by imparting strain or stress that changes (vibrates) over time to the sample and measuring stress or strain that is consequently generated. tan δ is measured in the tensile mode, whereby lateral movement with respect to an item to be polished is evaluated and thereby approached to the step elimination performance.

### <Cushion Layer>

### (Configuration)

The polishing pad 3 of the present invention has the cushion layer 6. It is desirable that the cushion layer 6 make the contact of the polishing layer 4 with the item to be polished 8 more uniform. Examples a material of the cushion layer 6 include resins; impregnated materials obtained by impregnating a base material with the resin; flexible materials such as synthetic resins or rubber; and sponge materials for which the resin is used. Examples of the resin include resins such as polyurethane, polyethylene, polybutadiene and silicone, rubber such as natural rubber, nitrile rubber and polyurethane rubber, and the like.

As the cushion layer 6, a foam or the like having a bubble structure may also be used. As the bubble structure, aside from structures in which voids have been formed in a non-woven fabric or the like, suede-like structures having tear-like bubbles formed by a wet-type film formation method or sponge-like structures in which fine bubbles have been formed can be preferably used.

Among these, when a foam obtained by impregnating a non-woven fabric with polyurethane or a sponge-like foam is used as the cushion layer, since compatibility with the polishing layer is favorable, it is possible to obtain a high polishing rate while the step elimination performance is maintained.

### <Adhesive Layer>

The adhesive layer 7 is a layer for making the cushion layer 6 and the polishing layer 4 adhere to each other and is normally composed of double-sided tape or an adhesive. As the double-sided tape or adhesive, it is possible to use double-sided tape or an adhesive (for example, adhesive sheet) that is well-known in the related art.

The polishing layer 4 and the cushion layer 6 are pasted to each other with the adhesive layer 7. The adhesive layer 7 can be formed of at least one pressure-sensitive adhesive selected from an acrylic pressure-sensitive adhesive, an epoxy-based pressure-sensitive adhesive and a urethane-based pressure-sensitive adhesive. For example, it is possible to use an acrylic pressure-sensitive adhesive and to set the thickness to 0.1 mm.

The polishing pad of the present invention is excellent in terms of defect performance while the step elimination performance is maintained and, furthermore, has excellent polishing rate or wear resistance.

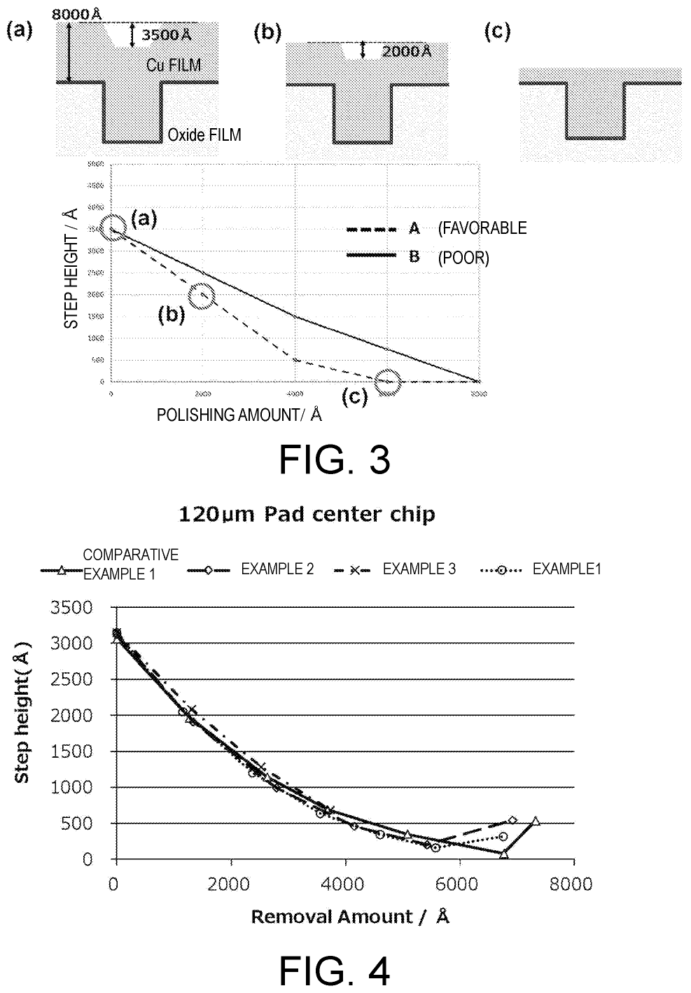

Here, the step elimination performance refers to performance for which the time taken for steps in patterned wafers having the steps (unevenness) to disappear as polishing progresses is used as an index. Pattern diagrams of a test for measuring the step elimination performance are shown in FIG. 3. Step elimination states in the case of using a polishing pad having high step elimination performance (dotted line) and in the case of using a polishing pad having relatively low step elimination performance (solid line) in a case where, for example, there are 3500-angstrom steps in an item to be polished are shown. While there is no difference at a point in time of (a) in FIG. 3, as polishing progresses, when the polishing amount reaches 2000 angstroms, it is shown that the time taken for the steps to disappear is short for the polishing pad having high step elimination performance (dotted line) compared with the polishing pad having relatively low step elimination performance (solid line) ((b)), and, with the polishing pad having high step elimination performance, the steps are eliminated relatively fast ((c)). The polishing pad indicated by the dotted line can be said to have relatively high step elimination performance than the polishing pad indicated by the solid line.

In addition, “defect” means a collective term for defects including “particle” indicating a remaining fine particle attached to the surface of an item to be polished, “pad debris” indicating debris of a polishing layer attached to the surface of the item to be polished, and “scratch” indicating a mark formed on the surface of the item to be polished, and defect performance refers to performance of decreasing the number of this “defect”.

In addition, the polishing rate is the amount of the surface of a wafer removed by polishing per unit time, and the characteristics becomes superior as the value becomes larger.

In addition, wear resistance refers to the resistance to wear of the polishing layer (polishing pad).

### <<Method for Manufacturing Polishing Pad>>

A method for manufacturing the polishing pad 3 of the present invention will be described.

### <Material of Polishing Layer>

As a material of the polishing layer 4, a polyurethane resin foam is used. Examples of a specific main component include materials that are obtained by reacting an isocyanate-terminated prepolymer and a curing agent. In addition, a blowing agent is added to the material in order for foaming.

Hereinafter, a method for manufacturing the polishing layer 4 will be described using an example where an isocyanate-terminated prepolymer and a curing agent are used.

A method for manufacturing the polishing layer 4 using an isocyanate-terminated prepolymer and a curing agent is, for example, a manufacturing method including a material preparation step of preparing at least an isocyanate-terminated prepolymer, an additive and a curing agent; a mixing step of mixing at least the isocyanate-terminated prepolymer, the additive and the curing agent to obtain a liquid mixture for molding a compact; and a molding step of molding the polishing layer 4 from the liquid mixture for molding a compact.

Hereinafter, the material preparation step, the mixing step and the molding step will be each described.

### <Material Preparation Step>

In order to manufacture the polishing layer 4 of the present invention, an isocyanate-terminated prepolymer and a curing agent are prepared as the raw materials of the polyurethane resin foam. Here, an isocyanate-terminated prepolymer is a urethane prepolymer for forming the polyurethane resin foam.

Hereinafter, each component will be described.

### (Isocyanate-Terminated Prepolymer)

The isocyanate-terminated prepolymer is a compound that is obtained by reacting a polyisocyanate compound and a polyol compound, which will be described below, under normally-used conditions and includes a urethane bond and an isocyanate group in the molecule. In addition, other components may be contained in the isocyanate-terminated prepolymer to an extent that the effect of the present invention is not impaired.

As the isocyanate-terminated prepolymer, a commercially available isocyanate-terminated prepolymer may be used or an isocyanate-terminated prepolymer synthesized by reacting a polyisocyanate compound and a polyol compound may be used. The reaction is not particularly limited, and an addition polymerization reaction may be performed using a method and conditions that are well-known in the manufacturing of polyurethane resins. For example, the urethane bond-containing polyisocyanate compound can be manufactured by a method in which a polyisocyanate compound heated to 50° C. is added to a polyol compound heated to 40° C. in a nitrogen atmosphere under stirring, after 30 minutes, the mixture is heated up to 80° C. and further reacted at 80° C. for 60 minutes.

The NCO equivalent of the isocyanate-terminated prepolymer is preferably approximately 300-600. Therefore, for the isocyanate-terminated prepolymer, in the case of a commercially available product, the NCO equivalent preferably satisfied the above-described range, and, when the isocyanate-terminated prepolymer is manufactured by synthesis, it is preferable to obtain an NCO equivalent within the above-described range using the following raw materials in appropriate proportions.

### (Polyisocyanate Compound)

In the present specification, the polyisocyanate compound means a compound having two or more isocyanate groups in the molecule.

The polyisocyanate compound is not particularly limited as long as two or more isocyanate groups are present in the molecule. Examples of a diisocyanate compound having two isocyanate groups in the molecule include m-phenylene diisocyanate, p-phenylene diisocyanate, 2,6-tolylene diisocyanate (2,6-TDI), 2,4-tolylene diisocyanate (2,4-TDI), naphthalene-1,4-diisocyanate, diphenylmethane-4,4′-diisocyanate (MDI), 4,4′-methylene-bis(cyclohexyl isocyanate) (hydrogenated MDI), 3,3′-dimethoxy-4,4′-biphenyl diisocyanate, 3,3′-dimethyldiphenylmethane-4,4′-diisocyanate, xylylene-1,4-diisocyanate, 4,4′-diphenylpropane diisocyanate, trimethylene diisocyanate, hexamethylene diisocyanate, propylene-1,2-diisocyanate, butylene-1,2-diisocyanate, cyclohexylene-1,2-diisocyanate, cyclohexylene-1,4-diisocyanate, p-phenylene diisothiocyanate, xylylene-1,4-diisothiocyanate, ethylidine diisothiocyanate and the like. These polyisocyanate compounds may be used singly or a plurality of polyisocyanate compounds may be used in combination.

As the polyisocyanate compound, 2,4-TDI and/or 2,6-TDI is preferably contained.

### (Polyol Compound as Raw Material of Isocyanate-Terminated Prepolymer)

In the present specification, the polyol compound means a compound having two or more hydroxyl groups (OH) in the molecule.

Examples of the polyol compound that is used to synthesize the urethane bond-containing polyisocyanate compound, which is the isocyanate-terminated prepolymer, include diol compounds such as ethylene glycol, diethylene glycol (hereinafter, also referred to as DEG) and butylene glycol, triol compounds and the like; and polyether polyol compounds such as poly(oxytetramethylene) glycol (or polytetramethylene ether glycol) (hereinafter, also referred to as PTMG), polypropylene glycol (hereinafter, also referred to as PPG) and polyether polycarbonate diol (hereinafter, also referred to as PEPCD). In the present specification, the polyether polycarbonate diol includes two or more ether-based polyol parts and two or more carbonate groups.

The number of carbon atoms in the ether-based polyol parts in the polyether polycarbonate diol is not particularly limited and is, for example, 2-8, the ether-based polyol part may be linear and may have a branched chain.

PEPCD is a compound represented by the following general formula.

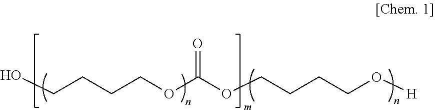

In the formula, m and n represent the number of repetitions of a unit and each independently represent a real number. One kind of PEPCD can be used or two or more kinds can also be used in combination.

Examples of commercially available polyether polycarbonate diols include PEPCDNT1002, PEPCDNT2002, PEPCDNT2006 (all manufactured by Mitsubishi Chemical Corporation) and the like.

The number-average molecular weight of the polyether polycarbonate diol is not particularly limited, but the polyether polycarbonate diol preferably has a number-average molecular weight of 600-2500 from the viewpoint of exhibiting rubber elasticity necessary for the polishing pad as the soft segment.

Among the above-described components, PPG and PEPCD are preferable, and a combination of PPG and PEPCD is preferable from the viewpoint of easily adjusting NC80/NC40 to 1.5-2.5, in addition, the viewpoint of easily adjusting the value of Expression (1) to 1.20-1.50 and, furthermore, the viewpoint of easily adjusting the value of Expression (2) to 0.70-1.30.

In the case of the combination of PPG and PEPCD, there is less than 80 weight % of the polypropylene glycol to be used with respect to the entire high-molecular-weight polyol. When the amount exceeds 80 weight %, the wear resistance becomes poor. There is preferably 30-70 weight % of the polypropylene glycol with respect to the entire high-molecular-weight polyol.

In addition, there is less than 80 weight % of the polyether polycarbonate diol with respect to the entire high-molecular-weight polyol. When the amount exceeds 80 weight %, the wear resistance becomes poor. There is preferably 30-70 weight % of the polyether polycarbonate diol with respect to the entire high-molecular-weight polyol. The total amount of the polypropylene glycol and the polyether polycarbonate diol is preferably 80 weight % or more with respect to the entire high-molecular-weight polyol. This is because, when the total amount is 80 weight % or more, the effect is significantly exhibited.

In the present invention, as the high-molecular-weight polyol, a high-molecular-weight polyol other than the polypropylene glycol and the polyether polycarbonate diol may be used as necessary, but is used to an extent that the effect of the present invention is not impaired. There is preferably 10 weight % or less of the polyoxytetramethylene glycol, more preferably 5 weight % or less and still more preferably 3 weight % or less with respect to the entire high-molecular-weight polyol. When there is more than 10 weight % of the polyoxytetramethylene glycol or the like, there are cases where the step elimination performance or the defect performance becomes insufficient.

The number-average molecular weight (Mn) of the polyol such as PPG or PEPCD is not particularly limited, but is, for example, preferably 500 or more, more preferably 500-3000 and still more preferably set to 800-2500, and the polyol may have a number-average molecular weight (Mn) of, for example, 500-2000 or, for example, 650-1000.

Here, the number-average molecular weight can be measured by gel permeation chromatography (GPC). In the case of measuring the number-average molecular weight of the polyol compound from the polyurethane resin, it is also possible to estimate the number-average molecular weight by GPC after each component is decomposed by a normal method such as amine decomposition.

### (Additive)

As described above, as the material of the polishing layer 4, an additive, such as an oxidant, can be added as necessary.

### (Curing Agent)

In the method for manufacturing the polishing layer 4 of the present invention, a curing agent (also referred to as a chain extender) is mixed with the isocyanate-terminated prepolymer or the like in the mixing step. When the curing agent is added, in a subsequent compact molding step, a main chain end of the isocyanate-terminated prepolymer bonds to the curing agent to form a polymer chain, and the urethane bond-containing polyisocyanate compound cures.

Examples of the curing agent include polyvalent amine compounds such as ethylenediamine, propylenediamine, hexamethylenediamine, isophoronediamine, dicyclohexylmethane-4,4′-diamine, 3,3′-dichloro-4,4′-diaminodiphenylmethane (MOCA), 4-methyl-2,6-bis(methylthio)-1,3-benzenediamine, 2-methyl-4,6-bis(methylthio)-1,3-benzenediamine, 2,2-bis(3-amino-4-hydroxyphenyl)propane, 2,2-bis[3-(isopropylamino)-4-hydroxyphenyl]propane, 2,2-bis[3-(1-methylpropylamino)-4-hydroxyphenyl]propane, 2,2-bis[3-(1-methylpentylamino)-4-hydroxyphenyl]propane, 2,2-bis(3,5-diamino-4-hydroxyphenyl)propane, 2,6-diamino-4-methylphenol, trimethylethylene bis-4-aminobenzonate and polytetramethylene oxide-di-p-aminobenzonate; and polyvalent alcohol compounds such as ethylene glycol, propylene glycol, diethylene glycol, trimethylene glycol, tetraethylene glycol, triethylene glycol, dipropylene glycol, 1,4-butanediol, 1,3-butanediol, 2,3-butanediol, 1,2-butanediol, 3-methyl-1,2-butanediol, 1,2-pentanediol, 1,4-pentanediol, 2,4-pentanediol, 2,3-dimethyltrimethylene glycol, tetramethylene glycol, 3-methyl-4,3-pentanediol, 3-methyl-4,5-pentanediol, 2,2,4-trimethyl-1,3-pentanediol, 1,6-hexanediol, 1,5-hexanediol, 1,4-hexanediol, 2,5-hexanediol, 1,4-cyclohexanedimethanol, neopentyl glycol, glycerin, trimethylolpropane, trimethylolethane, trimethylolmethane, poly(oxytetramethylene) glycol, polyethylene glycol and polypropylene glycol. In addition, the polyvalent amine compounds may have a hydroxyl group, and examples of such amine-based compound include 2-hydroxyethylethylenediamine, 2-hydroxyethylpropylenediamine, di-2-hydroxyethylethylenediamine, di-2-hydroxyethylpropylenediamine, 2-hydroxypropylethylenediamine, di-2-hydroxypropylethylenediamine and the like. As the polyvalent amine compounds, diamine compounds are preferable, and, for example, 3,3′-dichloro-4,4′-diaminodiphenylmethane (methylenebis-o-chloroaniline) (hereinafter, abbreviated as MOCA) is more preferably used.

In a case where two or more kinds of polyols are used as the raw material of the prepolymer, a prepolymer obtained by mixing two or more kinds of polyols and reacting a polyisocyanate compound with the mixture may be used or the two or more kinds of polyols may be each reacted with a polyisocyanate compound, then, the reaction products may be mixed together and cured in the method.

The polishing layer 4 can be molded using the hollow microspheres 4A each having an outer shell and being hollow inside as a material. As a material of the hollow microspheres 4, a commercially available material may be used or a material synthesized by a normal method and thus obtained may also be used. A material of the outer shell of the hollow microsphere 4A is not particularly limited, and examples thereof include polyvinyl alcohol, polyvinylpyrrolidone, poly(meth)acrylic acid, polyacrylamide, polyethylene glycol, polyhydroxy ether acrylate, maleic acid copolymers, polyethylene oxide, polyurethane, poly(meth)acrylonitrile, polyvinylidene chloride, polyvinyl chloride, organic silicone-based resins and copolymers obtained by combining two or more monomers that configure these resins (examples thereof include acrylonitrile-vinylidene chloride copolymers and the like). In addition, commercially available hollow microspheres are not limited to the followings, but examples thereof include EXPANCEL series (trade name manufactured by Akzo Nobel N.V.), MATSUMOTO MICROSPHERE (trade name manufactured by Matsumoto Yushi-Seiyaku Co., Ltd.) and the like.

The gas that is contained in the hollow microspheres 4 is not particularly limited, examples thereof include hydrocarbons, and specific examples thereof include isobutane, pentane, isopentane and the like.

The shape of the hollow microsphere 4A is not particularly limited and may be, for example, a spherical shape and a substantially spherical shape. The average particle diameter of the hollow microspheres 4A is not particularly limited, but is preferably 5-200 μm, more preferably 5-80 μm, still more preferably 5-50 μm and particularly preferably 5-35 μm. The average particle diameter can be measured with a laser diffraction-type particle size distribution-measuring instrument (for example, MASTERSIZER 2000 manufactured by Spectris).

The amount of the material of the hollow microspheres 4A added is preferably 0.1-10 parts by mass, more preferably 1-5 parts by mass and still more preferably 1-4 parts by mass with respect to 100 parts by mass of the isocyanate-terminated prepolymer.

In addition, apart from the above-described components, a blowing agent that has been conventionally used may be jointly used with the hollow microspheres 4A to an extent that the effect of the present invention is not impaired, and a non-reactive gas may be blown to each of the components in the mixing step. Examples of the blowing agent include, apart from water, blowing agents containing hydrocarbon having 5 or 6 carbon atoms as a main component. Examples of the hydrocarbon include chain hydrocarbons such as n-pentane and n-hexane and alicyclic hydrocarbons such as cyclopentane and cyclohexane.

The hollow microspheres 4A that may be included in the polishing layer 4 in the polishing pad of the present invention can be confirmed as hollow bodies on the polishing surface of the polishing layer 4 or a cross-section of the polishing layer 4, and the hollow bodies normally have opening diameters (diameters of the hollow microspheres 4) of 2-200 μm. Examples of the shape of the hollow microsphere 4A include a spherical shape, an elliptical shape and shapes close thereto.

As the hollow microspheres 4A, commercially available balloons can be used, and examples thereof include already-expanded balloons and unexpanded balloons. The unexpanded balloons are thermal expandable microspheres and can be expanded by heating. In the present invention, the unexpanded balloons may be used after being expanded by heating or the unexpanded balloons may be mixed with the mixture in an unexpanded state and expanded by heating, heat from reaction heat or the like during the reaction.

### <Mixing Step>

In the mixing step, the isocyanate-terminated prepolymer, the additive and the curing agent obtained in the preparation step are supplied to a mixer and stirred and mixed together. The mixing step is performed in a state where the components have been heated to a temperature where the fluidity of each of the components can be secured.

### <Molding Step>

In the compact molding step, a liquid mixture for molding a compact prepared in the mixing step is made to flow into a formwork preheated to 30-100° C. and primarily cured, then, heated at approximately 100-150° C. for approximately 10 minutes to five hours to be secondarily cured, thereby molding a cured polyurethane resin (polyurethane resin foam). At this time, the polyurethane resin cures due to the reaction between the isocyanate-terminated prepolymer and the curing agent to form a cured polyurethane resin.

When the viscosity is too high, the fluidity becomes poor, and it becomes difficult to mix the urethane prepolymer (isocyanate-terminated prepolymer) substantially uniformly during mixing. When the viscosity is decreased by increasing the temperature, the pot life becomes short, conversely, mixed stains are generated, and a variation is caused in the sizes of the hollow microspheres 4A that are formed in a foam to be obtained. On the contrary, when the viscosity is too low, bubbles move in the liquid mixture, and it becomes difficult to form the hollow microspheres 4A that have substantially evenly dispersed in a foam to be obtained. Therefore, the viscosity of the prepolymer is preferably set within a range of 500-10000 mPa·s at a temperature of 50-80° C. Regarding this, the viscosity can be set by, for example, changing the molecular weight (degree of polymerization) of the prepolymer. The prepolymer is heated to approximately 50-80° C. and put into a flowable state.

In the molding step, the liquid mixture cast as necessary is reacted in the framework to form a foam. At this time, the prepolymer crosslink-cures by the reaction between the prepolymer and the curing agent.

After a compact is obtained, the compact is sliced in a sheet shape to form a plurality of polishing layers 4. For the slicing, an ordinary slicing machine can be used. During the slicing, the compact is sequentially sliced from the upper layer part to a predetermined thickness while the lower layer part of the polishing layer 4 is held. The thickness to be sliced is set, for example, within a range of 0.8-2.5 mm. In a foam molded with a 50 mm-thick framework, for example, approximately 10 mm parts in the upper layer part and the lower layer part of the foam cannot be used due to scratches or the like, and 10-25 polishing layers 4 are formed from the approximately 30 mm central part. A foam in which the hollow microspheres 4A have been substantially evenly formed is obtained in the curing molding step.

Grooving is performed on a polishing surface of the obtained polishing layer 4 as necessary. A cutting process or the like is performed on the polishing surface using a necessary cutter, whereby grooves having arbitrary pitches, widths and depths can be formed. Examples of the slurry holding grooves include circular grooves formed in a concentric circular shape, and examples of the slurry discharge grooves include linear grooves formed in a lattice shape, linear grooves radially formed from the center of the polishing layer and the like.

In the polishing layer 4 thus obtained, after that, double-sided tape is pasted to a surface opposite to the polishing surface of the polishing layer 4. The double-sided tape is not particularly limited, and double-sided tape can be arbitrarily selected from double-sided tapes that are well-known in the related art and used.

### <Method for Manufacturing Cushion Layer 6>

As described above, as a material of the cushion layer 6, a well-known material can be used, and, as a manufacturing method as well, a well-known manufacturing method can be used. Examples of the material of the cushion layer 6 include impregnated materials obtained by impregnating a resin fiber (a non-woven fabric, a flexible film or the like) such as polyethylene or polyester with a resin solution of urethane or the like; suede materials for which a resin material such as urethane is used; and sponge materials for which a material such as urethane is used.

The cushion layer 6 is preferably composed of an impregnated non-woven fabric impregnated with a resin. Preferable examples of the resin that is used to impregnate the non-woven fabric include polyurethanes such as polyurethane and polyurethane polyurea, acrylics such as polyacrylate and polyacrylonitrile, vinyls such as polyvinyl chloride, polyvinyl acetate and polyvinylidene fluoride, polysulfones such as polysulfone and polyethersulfone, acylated celluloses such as acetylated cellulose and butyrylated cellulose, polyamides, polystyrenes and the like. The density of the non-woven fabric before being impregnated with the resin (in a web state) is preferably 0.3 g/cm³ or less and more preferably 0.1-0.2 g/cm^{3 .} In addition, the density of the non-woven fabric after being impregnated with the resin is preferably 0.7 g/cm³ or less and more preferably 0.25-0.5 g/cm³. When the densities of the non-woven fabric before being impregnated with the resin and after being impregnated with the resin are the above-described upper limits or less, the processing accuracy improves. In addition, when the densities of the non-woven fabric before being impregnated with the resin and after being impregnated with the resin are the above-described lower limits or more, it is possible to reduce the permeation of the polishing slurry into a base material layer. The rate of the resin attached to the non-woven fabric is represented by the weight of the resin attached with respect to the weight of the non-woven fabric and is preferably 50 weight % or more and more preferably 75-200 weight %. When the rate of the resin attached to the non-woven fabric is the above-described upper limit or less, it is possible for the cushion layer to have desired cushioning properties.

### <Joining Step>

In a joining step, the formed polishing layer 4 and cushion layer 6 are pasted (joined) to each other with the adhesive layer 7. As the adhesive layer 7, for example, an acrylic pressure-sensitive adhesive is used, and the adhesive layer 7 is formed so as to be 0.1 mm in thickness. That is, the acrylic pressure-sensitive adhesive is applied onto the surface of the polishing layer 4 opposite to the polishing surface in a substantially uniform thickness. The surface of the polishing layer 4 opposite to the polishing surface P and the surface (surface on which the skin layer has been formed) of the cushion layer 6 are pressed against each other across the applied pressure-sensitive adhesive, thereby pasting the polishing layer 4 and the cushion layer 6 to each other with the adhesive layer 7. In addition, the laminate is cut into a desired shape such as a circular shape, an inspection is performed to confirm whether or not dirt, foreign matters or the like are attached, and the polishing pad 3 is completed.

### EXAMPLES

Hereinafter, the present invention will be described in more detail with examples, but the present invention is not limited to these examples.

In each of the examples and comparative examples, “parts” means “parts by mass” unless particularly otherwise described.

In addition, an NCO equivalent is a numerical value indicating the molecular weight of a prepolymer (PP) per NCO group that is obtained by “(the mass (parts) of a polyisocyanate compound+the mass (parts) of a polyol compound)/[(the number of functional groups per molecule of the polyisocyanate compound×the mass (parts) of the polyisocyanate compound/the molecular weight of the polyisocyanate compound)−(the number of functional groups per molecule of the polyol compound×the mass (parts) of the polyol compound/the molecular weight of the polyol compound)].”

### Examples 1-3 and Comparative Example 1

### (Regarding Polishing Layer)

2,4-Tolylene diisocyanate (TDI) as an isocyanate compound and PPG, PTMG, PEPCD and diethylene glycol (DEG) as polyol compounds were reacted, thereby preparing urethane prepolymers 1, 2 and 3 (regarding components used to prepare the urethane prepolymers, refer to Table 1). 2.9 Parts of unexpanded hollow microspheres each having a shell part composed of an acrylonitrile-vinylidene chloride copolymer and containing an isobutane gas in the shell were added to and mixed with 100 parts of a urethane prepolymer mixture mixed in proportions shown in Table 2, thereby obtaining a liquid mixture. The obtained liquid mixture was charged into a first liquid tank and kept warm at 60° C. Next, separately from a first liquid, 27.8 parts of MOCA was put into a second liquid tank as a curing agent, heated and melted at 120° C. and kept warm. The respective liquids in the first liquid tank and the second liquid tank were injected into a mixer equipped with two inlets such that an R value, which indicates the equivalence ratio at each inlet of an amino group and a hydroxyl group present in the curing agent with respect to a terminal isocyanate group in the prepolymer, reached 0.9. The two injected liquids were injected into a mold of a preheated molding machine while being mixed and stirred, then, the mold was clamped, and a molding was heated at 80° C. for 30 minutes and primarily cured. The primarily-cured molding was released from the mold and then secondarily cured in an oven at 120° C. for four hours, thereby obtaining a urethane molding. The obtained urethane molding was naturally cooled to 25° C., then, heated again in the oven at 120° C. for five hours and then sliced in a thickness of 1.3 mm, thereby obtaining polishing layers 1 to 4 shown in Table 2. In addition, the density and D hardness of each polishing layer are shown in Table 3, and the proportions of a crystalline phase, an intermediate phase and an amorphous phase obtained using pulse NMR are shown in Table 4. Measurement methods and conditions for the density, the D hardness and the pulse NMR measurement are as described below.

### (Density)

The densities (g/cm³) of the polishing layers were measured according to Japanese Industrial Standards (JIS K 6505).

### (Shore D Hardness)

The shore D hardness of the polishing layers was measured using a shore D-type hardness meter according to Japanese Industrial Standards (JIS-K-6253). Here, a measurement sample was obtained by overlaying a plurality of the polishing layers as necessary so that the total thickness reached at least 4.5 mm or greater.

### (Pulse NMR Measurement)

| | |
|---|---|
| Device | Minispec mq20 (20 MHz) manufactured |
| | by Bruker |
| Repetition time | Four seconds |
| Measurement method | Solid echo method |
| Cumulated number | 16 times |
| Measurement temperature | 40° C. and 80° C. |

TABLE 1

| | NCO equivalent | Composition | Note |
|---|---|---|---|
| Prepolymer 1 | 420 | 2,4-TDI/PPG/DEG | PPG having a number-average molecular |
| | | | weight of approximately 1000 |
| Prepolymer 2 | 420 | 2,4-TDI/PTMG/DEG | PTMG having a number-average molecular |
| | | | weight of approximately 850 |
| Prepolymer 3 | 420 | 2,4-TDI/PEPCD/DEG | PEPCD having a number-average molecular |
| | | | weight of approximately 1000 |

TABLE 2

| | | | PPG | | |
|---|---|---|---|---|---|
| | | Prepolymer | compounding | Curing | |
| | Urethane prepolymer | composition | ratio | agent | Microspheres |
| Polishing layer 1 | Prepolymer 2 | PTMG: 100% | 0 | MOCA | Unexpanded |
| (Comparative | | | | | |
| Example 1) | | | | | |
| Polishing layer 2 | Prepolymer | PPG:PEPCD = 7:3 | 70 | MOCA | Unexpanded |
| (Example 1) | 1 + Prepolymer 3 | | | | |
| Polishing layer 3 | Prepolymer | PPG:PEPCD = 5:5 | 50 | MOCA | Unexpanded |
| (Example 2) | 1 + Prepolymer 3 | | | | |
| Polishing layer 4 | Prepolymer | PPG:PEPCD = 3:7 | 30 | MOCA | Unexpanded |
| (Example 3) | 1 + Prepolymer 3 | | | | |

TABLE 3

| | Density (g/cm³) | D hardness (degrees) |
|---|---|---|
| Polishing layer 1 | 0.783 | 62.0 |
| (Comparative Example 1) | | |
| Polishing layer 2 | 0.780 | 63.5 |
| (Example 1) | | |
| Polishing layer 3 | 0.781 | 63.5 |
| (Example 2) | | |
| Polishing layer 4 | 0.778 | 63.5 |
| (Example 3) | | |

TABLE 4

| | | | | | | | | Value of (value at 80° C./ | | | |
|---|---|---|---|---|---|---|---|---|---|---|---|
| | 40° C. | | | 80° C. | | | | value at 40° C.) of each phase | | | |
| | | Inter- | | | Inter- | | Value of | | Inter- | | Value of |
| | Crystalline | mediate | Amorphous | Crystalline | mediate | Amorphous | (NC80/ | Crystalline | mediate | Amorphous | formula |
| | phase | phase | phase | phase | phase | phase | NC40) | phase | phase | phase | (1) |
| Comparative | 49.43 | 24.85 | 25.73 | 38.89 | 25.23 | 35.88 | 1.39 | 0.79 | 1.02 | 1.39 | 0.61 |
| Example 1 | | | | | | | | | | | |
| Example 1 | 52.11 | 32.19 | 15.70 | 38.44 | 31.11 | 30.45 | 1.94 | 0.74 | 0.97 | 1.94 | 1.20 |
| Example 2 | 53.61 | 30.70 | 15.69 | 37.46 | 31.25 | 31.29 | 1.99 | 0.70 | 1.02 | 1.99 | 1.30 |
| Example 3 | 54.78 | 29.94 | 15.28 | 38.72 | 30.96 | 30.32 | 1.98 | 0.71 | 1.03 | 1.98 | 1.28 |

### (Regarding Cushion Layer)

A non-woven fabric composed of polyester fibers having a density of 0.15 g/cm³ was immersed in a resin solution (DMF solvent) containing a urethane resin (manufactured by DIC Corporation, trade name “C1367”). After the immersion, the resin solution was squeezed from the non-woven fabric using a mangle roller capable of pressurization between a pair of rollers to substantially uniformly impregnate the non-woven fabric with the resin solution. Next, the non-woven fabric impregnated with the resin solution was immersed in a coagulating liquid composed of water of room temperature, thereby coagulating the resin in a wet manner and obtaining a resin-impregnated non-woven fabric. After that, the resin-impregnated non-woven fabric was removed from the coagulating liquid, furthermore, washed with a washing liquid composed of water to remove N,N-dimethylformamide (DMF) in the resin and dried. After the drying, a skin layer on the surface of the resin-impregnated non-woven fabric was removed by a buffing treatment, thereby obtaining a 1.3 mm-thick cushion layer composed of the resin-impregnated non-woven fabric.

### Examples and Comparative Examples

Each of the polishing layers 1-4 and the cushion layer were joined with 0.1 mm-thick double-sided tape (tape including adhesive layers composed of an acrylic resin on both surfaces of a PET base material), and double-sided tape was pasted onto the surface opposite to the cushion layer and the adhesive layer, thereby manufacturing a polishing pad of each of Examples 1-3 and Comparative Example 1.

### (Polishing Performance Evaluation)

Polishing tests were performed using the obtained polishing pads of Examples 1 to 3 and Comparative Example 1 under the following polishing conditions. The results are shown in Table 5.

### (Polishing Conditions)

Polishing machine used: F-REX300X (manufactured by Ebara Corporation)
Disk: A188 (manufactured by 3M Company)
Abrasive temperature: 20° C.
Polishing surface plate rotation speed: 90 rpm
Polishing head rotation speed: 81 rpm
Polishing pressure: 3.5 psi
Polishing slurry (metal film): CSL-9044C (a liquid mixture of CSL-9044C undiluted solution and pure water in a weight ratio of 1:9 was used) (manufactured by Fujifilm Digital Solutions Co., Ltd.)
Polishing slurry flow rate: 200 ml/min.
Polishing time: 60 sec.
Item to be polished: Cu film substrate (polishing performance evaluation test), patterned wafer to be described below (step elimination performance test)
   Pad break: 32 N 10 min.
Conditioning: In-situ 18 N 16 scan, Ex-situ 32 N 4 scan

The polishing rates (thicknesses polished for a polishing time of 60 seconds) of the 15^{th} , 25^{th} and 50^{th} polished substrates were measured. In the examples, the polishing rates were evaluated with the polished thicknesses.

TABLE 5

| | Polishing rate (Å) | | |
|---|---|---|---|
| | 15^{th} | 25^{th} | 50^{th} |
| Comparative Example 1 | 8932 | 9062 | 9012 |
| Example 1 | 9764 | 9953 | 9925 |
| Example 2 | 9673 | 9479 | 9972 |
| Example 3 | 9504 | 9753 | 9886 |

### (Polishing Test Result Discussion)

From the results of Table 5, it was found that, in the polishing pads of Examples 1-3, the polishing rates improved and the polishing performance was excellent compared with that of the polishing pad of Comparative Example 1.

### (Step Elimination Performance Test)

The polishing pad of each of the examples and the comparative example was installed at a predetermined position in a polishing device through double-sided tape having an acrylic adhesive, and a polishing process was performed under the above-described polishing conditions. The step elimination performance was evaluated by measuring 100 μm/100 μm dishing with a step/surface roughness/fine shape measuring instrument (manufactured by KLA-Tencor Corporation, P-16+). The evaluation results are shown in FIG. 4.

Polishing was performed on a patterned wafer having a 7000-angstrom film thickness and 3000-angstrom steps at a polishing rate adjusted so that the polishing amount each time reached 1000 angstroms, polishing was performed stepwise, and the steps on the wafer were measured each time. “Step height” along the vertical axis indicates steps.

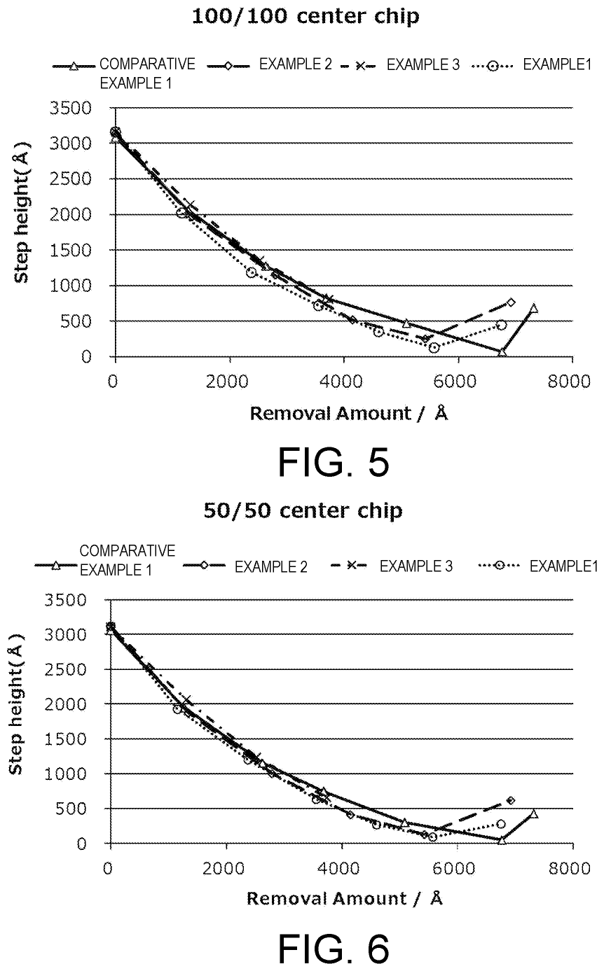

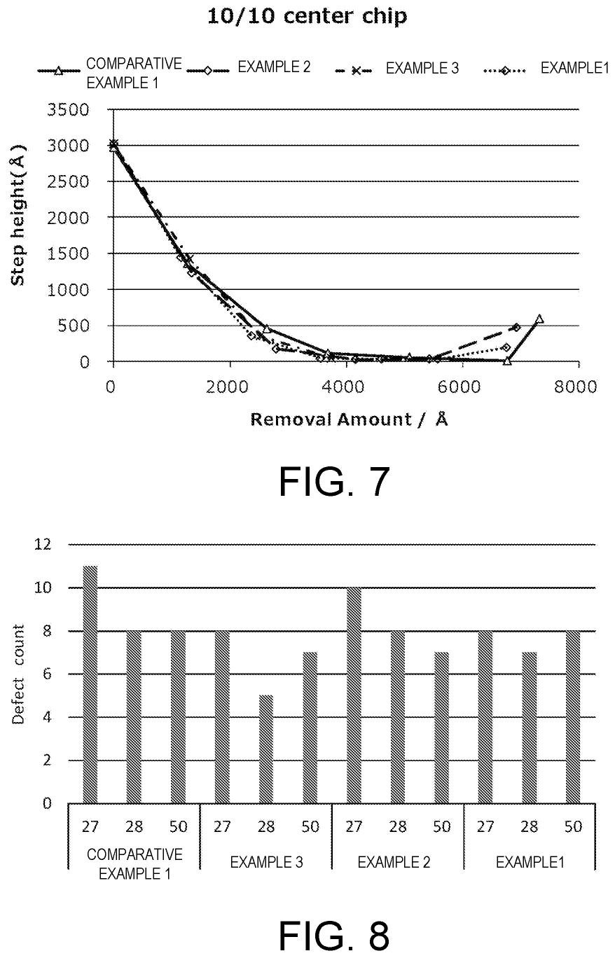

120 μm in FIG. 4 indicates polishing of a wiring having a wiring width of 120 μm, 100/100 in FIG. 5 indicates a wiring in which the width of an insulating film was 100 μm with respect to a Cu wiring width of 100 μm, 50/50 in FIG. 6 indicates a wiring in which the width of an insulating film was 50 μm with respect to a Cu wiring width of 50 μm, 10/10 in FIG. 7 indicates a wiring in which the width of an insulating film was 10 μm with respect to a Cu wiring width of 10 μm, and it is indicated that the wirings become finer as the numbers become smaller.

From the results of FIGS. 4-7, it was found that the polishing pads of Examples 1-3 had equivalent step performance to that of the polishing pad of Comparative Example 1.

### (Defect Performance Evaluation)

Micro scratches (fine dent-like scratches that were 0.02 μm or greater and 0.16 μm or less) on the substrate surface were detected using a high-sensitivity measurement mode of a surface inspection device (manufactured by KLA Corporation, SURFSCAN SP2XP) from the 27^{th}, 28^{th} and 50^{th} polished substrates and the numbers thereof were measured. The results are shown in FIG. 8.

From the results of FIG. 8, it was found that, in the polishing pads of Examples 1-3, the numbers of micro scratches slightly decreased compared with that of Comparative Example 1 and the generation of defects could be suppressed.

### Examples 4-6 and Comparative Examples 2 and 3

### (Regarding Polishing Layer)

2,4-Tolylene diisocyanate (TDI) as an isocyanate compound and PPG and PEPCD as polyol compounds were reacted, thereby preparing isocyanate-terminated prepolymers 4 and 5 (regarding components used to prepare the urethane prepolymers, refer to Table 6). 2.7 Parts of already-expanded hollow microspheres each having a shell part composed of an acrylonitrile-vinylidene chloride copolymer and containing an isobutane gas in the shell were added to and mixed with 100 parts of each of the isocyanate-terminated prepolymers prepared in proportions shown in Table 7, thereby obtaining a liquid mixture. The obtained liquid mixture was charged into a first liquid tank and kept warm at 60° C. Next, separately from a first liquid, 23.5 parts of MOCA was put into a second liquid tank as a curing agent, heated and melted at 120° C. and kept warm. The respective liquids in the first liquid tank and the second liquid tank were injected into a mixer equipped with two inlets such that an R value, which indicates the equivalence ratio at each inlet of an amino group and a hydroxyl group present in the curing agent with respect to a terminal isocyanate group in the prepolymer, reached 0.9. The two injected liquids were injected into a mold of a preheated molding machine while being mixed and stirred, then, the mold was clamped, and a molding was heated at 80° C. for 30 minutes and primarily cured. The primarily-cured molding was released from the mold and then secondarily cured in an oven at 120° C. for four hours, thereby obtaining a urethane molding. The obtained urethane molding was naturally cooled to 25° C., then, heated again in the oven at 120° C. for five hours and then sliced in a thickness of 1.3 mm, thereby obtaining polishing layers 5 to 9 shown in Table 7. In addition, the density and shore D hardness of each polishing layer are shown in Table 8, and the proportions of a crystalline phase, an intermediate phase and an amorphous phase are shown in Table 9. A measurement method and conditions for pulse NMR measurement are as described below.

### (Density)

The densities (g/cm³) of the polishing layers were measured according to Japanese Industrial Standards (JIS K 6505).

### (Shore D Hardness)

The shore D hardness of the polishing layers was measured using a D-type hardness meter according to Japanese Industrial Standards (JIS-K-6253). Here, a measurement sample was obtained by overlaying a plurality of the polishing layers as necessary so that the total thickness reached at least 4.5 mm or greater.

### (Pulse NMR Measurement)

| | |
|---|---|
| Device | Minispec mq20 (20 MHz) manufactured |
| | by Bruker |
| Repetition time | Four seconds |
| Measurement method | Solid echo method |
| Cumulated number | 16 times |
| Measurement temperature | 40° C. and 80° C. |

TABLE 6

| | NCO equivalent | Composition | Note |
|---|---|---|---|
| Prepolymer 4 | 500 | 2,4-TDI/PPG/DEG | PPG having a number-average molecular |
| | | | weight of approximately 1200 |
| Prepolymer 5 | 500 | 2,4-TDI/PEPCD/DEG | PEPCD having a number-average molecular |
| | | | weight of approximately 1000 |

TABLE 7

| | | | PPG | | |
|---|---|---|---|---|---|
| | | Prepolymer | compounding | Curing | |
| | Urethane Prepolymer | Composition | ratio | agent | Microspheres |
| Polishing layer 5 | Prepolymer 4 | PPG: 100% | 100 | MOCA | Already |
| (Comparative Example 2) | | | | | expanded |
| Polishing layer 6 | Prepolymer 4 + | PPG:PEPCD = 7:3 | 70 | MOCA | Already |
| (Example 4) | Prepolymer 5 | | | | expanded |
| Polishing layer 7 | Prepolymer 4 + | PPG:PEPCD = 5:5 | 50 | MOCA | Already |
| (Example 5) | Prepolymer 5 | | | | expanded |
| Polishing layer 8 | Prepolymer 4 + | PPG:PEPCD = 3:7 | 30 | MOCA | Already |
| (Example 6) | Prepolymer 5 | | | | expanded |
| Polishing layer 9 | Prepolymer 5 | PEPCD: 100% | 0 | MOCA | Already |
| (Comparative Example 3) | | | | | expanded |

TABLE 8

| | Density (g/cm³) | D hardness (degrees) |
|---|---|---|
| Polishing layer 5 | 0.786 | 52.0 |
| (Comparative Example 2) | | |
| Polishing layer 6 | 0.820 | 54.5 |
| (Example 4) | | |
| Polishing layer 7 | 0.815 | 53.5 |
| (Example 5) | | |
| Polishing layer 8 | 0.833 | 53.0 |
| (Example 6) | | |
| Polishing layer 9 | 0.813 | 52.5 |
| (Comparative Example 3) | | |

TABLE 9

| | | | | | | | Value at 80° C., | | |
|---|---|---|---|---|---|---|---|---|---|
| | 40° C. | | | 80° C. | | | value at 40° C. | | Value of |
| | Crystalline | Intermediate | Amorphous | Crystalline | Intermediate | Amorphous | NC80/ | NC40/ | formula |
| | phase | phase | phase | phase | phase | phase | CC80 | CC40 | (1) |
| Comparative | 39.10 | 44.90 | 16.00 | 25.00 | 49.20 | 25.80 | 1.03 | 0.41 | 0.62 |
| Example 2 | | | | | | | | | |
| Example 4 | 38.20 | 45.90 | 15.90 | 24.00 | 43.00 | 33.00 | 1.38 | 0.42 | 0.96 |
| Example 5 | 39.70 | 43.10 | 17.20 | 24.90 | 43.20 | 31.90 | 1.28 | 0.43 | 0.85 |
| Example 6 | 39.90 | 42.10 | 18.00 | 24.80 | 41.90 | 33.40 | 1.35 | 0.45 | 0.90 |
| Comparative | 42.80 | 40.40 | 16.80 | 26.80 | 45.10 | 28.10 | 1.05 | 0.39 | 0.66 |
| Example 3 | | | | | | | | | |

### (Dynamic Viscoelasticity Measurement (tan δ))

DMA (dynamic viscoelasticity measurement) was performed using the polishing layers 5-9 as samples. Samples in a dry state that had been held in a constant temperature and humidity bath having a set temperature of 23° C. (21-25° C.) and a set relative humidity of 50% (45-55%) for 40 hours were obtained.

The dynamic viscoelasticity was measured in a tensile mode in a normal atmosphere (dry state). Other conditions are as described below. The ratio (E″/E′) between the obtained E″ (loss modulus) and E′ (storage modulus) was calculated, and tan δ was obtained. The result of Example 6 is shown in FIG. 9, and the result of Comparative Example 2 is shown in FIG. 10. The maximum value and minimum value of each data and a difference therebetween are summarized in Table 10.
Device: RSA-G2 (manufactured by TA Instruments.)
Sample sizes: 5 cm in length, 0.5 cm in width and 0.125 cm in thickness
Test mode: Tensile mode
Frequency: 10 rad/sec (1.6 Hz)
Measurement temperature: 20-100° C.
Strain range: 0.10%
Test length: 1 cm
Heating rate: 5.0° C./min.
Initial load: 148 g
Measurement intervals: 2 point/° C.

TABLE 10

| | Maximum value of tan δ at | Minimum value of tan δ at | Maximum value − |
|---|---|---|---|
| | 40° C. to 80° C. | 40° C. to 80° C. | minimum value |
| Comparative | 0.1762 | 0.1263 | 0.050 |
| Example 2 | | | |
| Example 4 | 0.1143 | 0.0904 | 0.024 |
| Example 5 | 0.1109 | 0.0888 | 0.022 |
| Example 6 | 0.1125 | 0.0911 | 0.021 |
| Comparative | 0.1315 | 0.1130 | 0.019 |
| Example 3 | | | |

### (Regarding Cushion Layer)

A non-woven fabric composed of polyester fibers having a density of 0.15 g/cm³ was immersed in a resin solution (DMF solvent) containing a urethane resin (manufactured by DIC Corporation, trade name “C1367”). After the immersion, the resin solution was squeezed from the non-woven fabric using a mangle roller capable of pressurization between a pair of rollers to substantially uniformly impregnate the non-woven fabric with the resin solution. Next, the non-woven fabric impregnated with the resin solution was immersed in a coagulating liquid composed of water of room temperature, thereby coagulating the resin in a wet manner and obtaining a resin-impregnated non-woven fabric. After that, the resin-impregnated non-woven fabric was removed from the coagulating liquid, furthermore, washed with a washing liquid composed of water to remove N,N-dimethylformamide (DMF) in the resin and dried. After the drying, a skin layer on the surface of the resin-impregnated non-woven fabric was removed by a buffing treatment, thereby obtaining a 1.3 mm-thick cushion layer composed of the resin-impregnated non-woven fabric.

### Examples and Comparative Examples

Each of the polishing layers 5-9 and the cushion layer were joined with 0.1 mm-thick double-sided tape (tape including adhesive layers composed of an acrylic resin on both surfaces of a PET base material), and double-sided tape was pasted onto the surface opposite to the cushion layer and the adhesive layer, thereby manufacturing a polishing pad of each of Examples 4 to 6 and Comparative Examples 2 and 3.

### (Wear Test)

A wear test was performed on the obtained polishing pads using a small friction and wear tester under the following conditions. After the wear test, the thicknesses (wear amounts) of the polishing layers were measured. The results are shown in Table 11.

### (Wear Test Conditions)

Polishing machine used: Small friction and wear tester
Indenter side: PAD (17ϕ)
Surface plate side: #180 sandpaper
Load: 300 g
Liquid: Water
Flow rate: 45 ml/min.
Surface plate rotation speed: 40 rpm
Time: 10 min.
Thickness measurement load: 300 g

TABLE 11

| | Wear amount (mm) |
|---|---|
| Comparative Example 2 | 0.21 |
| Example 4 | 0.13 |
| Example 5 | 0.12 |
| Example 6 | 0.10 |
| Comparative Example 3 | 0.10 |

When the PPG compounding ratio in the prepolymer increases, the wear amount becomes large, and the wear resistance deteriorates. It was found that, in a case where the compounding ratio of PPG was low, an increase in the wear amount was suppressed.

### (Step Elimination Performance Test)

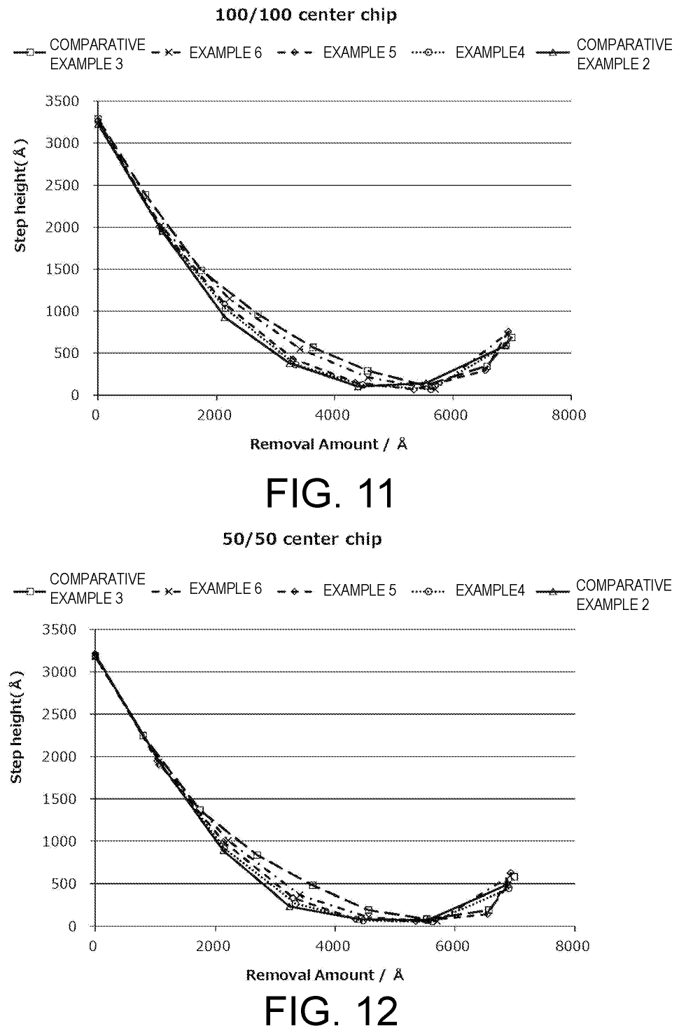

The polishing pad of each of the examples and the comparative examples was installed at a predetermined position in a polishing device through double-sided tape having an acrylic adhesive, and a polishing process was performed under the following conditions. The step elimination performance was evaluated by measuring 100 μm/100 μm dishing with a step/surface roughness/fine shape measuring instrument (manufactured by KLA-Tencor Corporation, P-16+). The evaluation results are shown in FIG. 11.

Polishing was performed on a patterned wafer having a 7000-angstrom film thickness and 3000-angstrom steps at a polishing rate adjusted so that the polishing amount each time reached 1000 angstroms, polishing was performed stepwise, and the steps on the wafer were measured each time. “Step height” along the vertical axis indicates steps.

100/100 in FIG. 11 indicates a wiring in which the width of an insulating film was 100 μm with respect to a Cu wiring width of 100 μm, 50/50 in FIG. 12 indicates a wiring in which the width of an insulating film was 50 μm with respect to a Cu wiring width of 50 μm, and it is indicated that the wirings become finer as the numbers become smaller.

### (Polishing Conditions)

Polishing machine used: F-REX300X (manufactured by Ebara Corporation)
Disk: A188 (manufactured by 3M Company)
Abrasive temperature: 20° C.
Polishing surface plate rotation speed: 90 rpm
Polishing head rotation speed: 81 rpm
Polishing pressure: 3.5 psi
Polishing slurry: CSL-9044C (a liquid mixture of CSL-9044C undiluted solution and pure water in a weight ratio of 1:9 was used) (manufactured by Fujifilm Digital Solutions Co., Ltd.)
Polishing slurry flow rate: 200 ml/min.
Polishing time: 60 sec.
Item to be polished: Pattered wafer described above
Pad break: 32 N 10 min.
Conditioning: In-situ 18 N 16 scan, Ex-situ 32 N 4 scan

From the results of FIG. 11, it was found that the polishing pads of Examples 4-6 had step elimination performance that was equivalent to that of the polishing pad of Comparative Example 2 and excellent compared with that of the polishing pad of Comparative Example 3.

### Examples 7-9 and Comparative Examples 4 and 5

### (Manufacturing of Polishing Layer)

3 Parts of unexpanded hollow microspheres each having a shell part composed of an acrylonitrile-vinylidene chloride copolymer and containing an isobutane gas in the shell were added to and mixed with 100 parts of an isocyanate-terminated urethane prepolymer having an NCO equivalent of 420 that had been formed by reacting 2,4-tolylene diisocyanate (TDI) and a high-molecular-weight polyol shown in Table 12, thereby obtaining a liquid mixture. The obtained liquid mixture was charged into a first liquid tank and kept warm. Next, separately from a first liquid, 28.6 parts of MOCA was charged into a second liquid tank as a curing agent and kept warm in the second liquid tank. The respective liquids in the first liquid tank and the second liquid tank were injected into a mixer equipped with two inlets such that an R value, which indicates the equivalence ratio at each inlet of an amino group and a hydroxyl group present in the curing agent with respect to a terminal isocyanate group in the prepolymer, reached 0.90. The two injected liquids were injected into a mold of a molding machine preheated to 80° C. while being mixed and stirred, then, the mold was clamped, and a molding was heated for 30 minutes and primarily cured. The primarily-cured molding was released from the mold and then secondarily cured in an oven at 120° C. for four hours, thereby obtaining a urethane molding. The obtained urethane molding was naturally cooled to 25° C., then, heated again in the oven at 120° C. for five hours and then sliced in a thickness of 1.3 mm, thereby obtaining each polishing layer.

### <Manufacturing of Cushion Layer>

A non-woven fabric composed of polyester fibers was immersed in a urethane resin solution (manufactured by DIC Corporation, trade name “C1367”). After the immersion, the resin solution was squeezed using a mangle roller capable of pressurization between a pair of rollers to substantially uniformly impregnate the non-woven fabric with the resin solution. Next, the non-woven fabric was immersed in a coagulating liquid composed of water of room temperature to coagulate and regenerate the impregnating resin, thereby obtaining a resin-impregnated non-woven fabric. After that, the resin-impregnated non-woven fabric was removed from the coagulating liquid, furthermore, immersed in a washing liquid composed of water to remove N,N-dimethylformamide (DMF) in the resin and then dried. After the drying, a skin layer on the surface was removed by a buffing treatment to produce a 1.3 mm-thick cushion layer.

### Examples and Comparative Examples

Each polishing layer formed of components shown in Table 12 and the cushion layer were joined with 0.1 mm-thick double-sided tape (tape including adhesives composed of an acrylic resin on both surfaces of a PET base material), thereby manufacturing a polishing pad of each of Examples 7-9 and Comparative Example 4. A polishing pad IC1000 (manufactured by NITTA DuPont Incorporated), which was conventionally well known, was used as Comparative Example 5.

In addition, PEPCD represents a polyether polycarbonate diol having a number-average molecular weight of 1000, PPG represents a polypropylene glycol having a number-average molecular weight of 1000, and PTMG represents a polyoxytetramethylene glycol having a number-average molecular weight of 850, respectively.

As Comparative Example 4, a polishing pad for which only PTMG was used as the high-molecular-weight polyol exhibiting equivalent density and hardness to those of Examples 7-9 was manufactured.

TABLE 12

| | Prepolymer | | | | | | |
|---|---|---|---|---|---|---|---|
| | | PPG | | | | | D |
| | High-molecular-weight | compounding | NCO | Curing | R | Density | hardness |
| | polyol weight ratio | ratio | equivalent | agent | value | (g/cm³) | (°) |
| Example 7 | PPG:PEPCD = 3:7 | 30 | 420 | MOCA | 0.90 | 0.778 | 63.5 |
| Example 8 | PPG:PEPCD = 5:5 | 50 | | | | 0.781 | 63.5 |
| Example 9 | PPG:PEPCD = 7:3 | 70 | | | | 0.780 | 63.5 |
| Comparative | PTMG:100% | 0 | | | | 0.783 | 62.0 |
| Example 4 | | | | | | | |

### (Density)

The densities (g/cm 3) of the polishing layers were measured according to Japanese Industrial Standards (JIS K 6505).

### (D Hardness)

The D hardness of the polishing layers was measured using a D-type hardness meter according to Japanese Industrial Standards (JIS-K-6253). Here, a measurement sample was obtained by overlaying a plurality of the polishing layers as necessary so that the total thickness reached at least 4.5 mm or greater.

### (Wear Test)

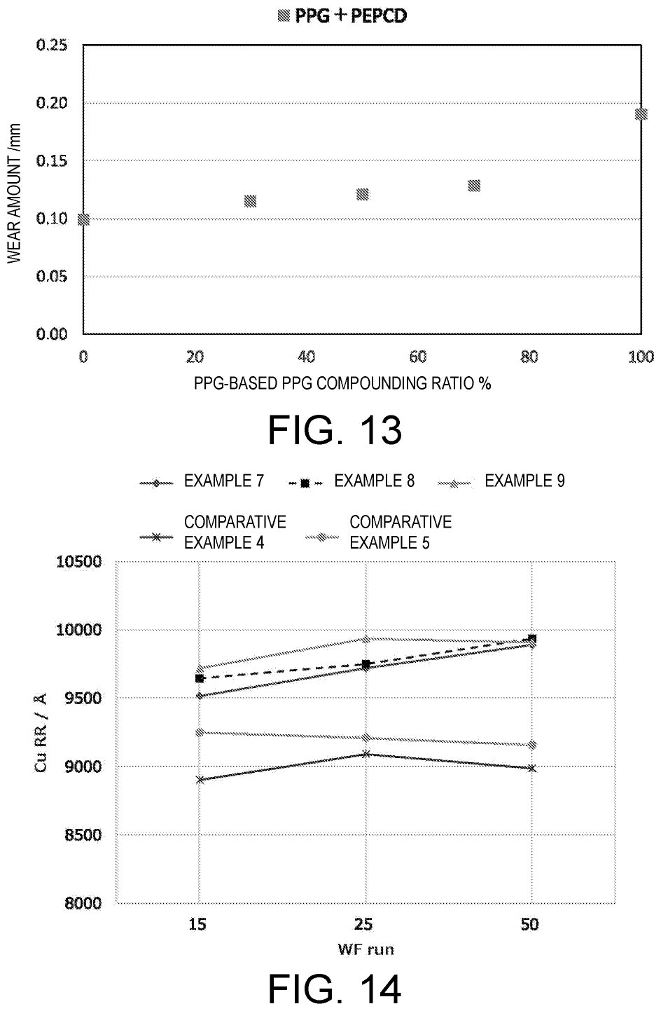

A wear test was performed on the obtained polishing pads using a small friction and wear tester under the following conditions. In FIG. 13, the wear amount (thickness) is indicated along the vertical axis, and the PPG compounding ratio is indicated along the horizontal axis.

### (Wear Test Conditions)

Polishing machine used: Small friction and wear tester
Indenter side: PAD (17ϕ)
Surface plate side: #180 sandpaper
Load: 300 g
Liquid: Water
Flow rate: 45 ml/min.
Surface plate rotation speed: 40 rpm
   Time: 10 min.
Thickness measurement load: 300 g

As is clear from FIG. 13, when the PPG compounding ratio in the high-molecular-weight polyol increases, the wear amount becomes large, and the wear resistance deteriorates. In a case where the compounding ratio of PPG is low, an increase in the wear amount is suppressed, on the other hand, when the compounding ratio of PPG exceeds a predetermined value, the wear amount abruptly increases.

For polishing pads having approximately equivalent polishing rates to Comparative Examples 4 and 5, the compounding ratio of PEPCD was set to 100%.

### (Polishing Performance Evaluation)

Polishing tests were performed using the obtained polishing pads of Examples 7-9 and Comparative Examples 4 and 5 under the following polishing conditions.

### (Polishing Conditions)

Polishing machine used: F-REX300X (manufactured by Ebara Corporation)
Disk: A188 (manufactured by 3M Company)
Abrasive temperature: 20° C.
Polishing surface plate rotation speed: 85 rpm
Polishing head rotation speed: 86 rpm
Polishing pressure: 3.5 psi
Polishing slurry (metal film): CSL-9044C (a liquid mixture of CSL-9044C undiluted solution and pure water in a weight ratio of 1:9 was used) (manufactured by Fujimi Corporation)
Polishing slurry flow rate: 200 ml/min.
Polishing time: 60 sec.
Item to be polished (metal film): Cu film substrate
Pad break: 35 N 10 min.
Conditioning: Ex-situ, 35 N, 4 scan

### (Polishing Rate)

The polishing pad was installed at a predetermined position in a polishing device through double-sided tape having an acrylic adhesive, and a polishing process was performed under the above-described polishing conditions. In addition, the polishing rates (unit: angstroms) of the 15^{th}, 25^{th} and 50^{th} polished substrates were measured. The results are shown in FIG. 14.

### (Defect Performance Evaluation)

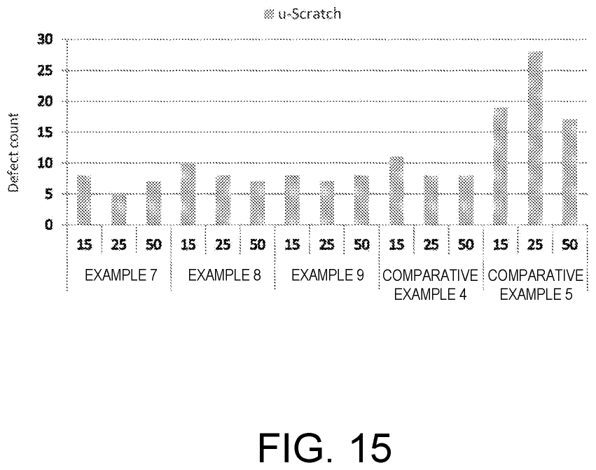

Defects (surface defects) that were 90 nm or greater were detected using a high-sensitivity measurement mode of a surface inspection device (manufactured by KLA Corporation, SURFSCAN SP2XP) from the 15^{th}, 25^{th} and 50^{th} polished substrates. Regarding each of the detected defects, analysis was performed on SEM images captured using a review SEM, and the number of scratches was measured. The results are shown in FIG. 15.

As is clear from FIG. 14, the polishing pads of Examples 7-9 had higher polishing rates by approximately 5-10% than the polishing pad of Comparative Example 4 showing the same density and hardness but containing only PTMG as the high-molecular-weight polyol or the polishing pad of Comparative Example 5, which was conventionally well known.

In addition, as is clear from FIG. 15, in the polishing pads of Examples 7-9, the number of scratches more significantly decreased than that of the polishing pad of Comparative Example 5, which was conventionally well known, and slightly decreased compared with Comparative Example 4, and excellent defect performance was exhibited.

### INDUSTRIAL APPLICABILITY

The present invention contributes to the manufacturing and sale of polishing pads and is thus industrially applicable.

### Reference Signs List

1 Polishing device
3 Polishing pad
4 Polishing layer
4A Hollow microsphere
6 Cushion layer
7 Adhesive layer
8 Item to be polished
9 Slurry
10 Polishing surface plate

1. A polishing pad comprising:
a polishing layer composed of a polyurethane resin foam derived from an isocyanate-terminated prepolymer and a curing agent,
wherein a ratio (NC80/NC40) of a content proportion by weight (NC80) of an amorphous phase in the polishing layer as measured by pulse NMR at 80° C. to a content proportion by weight (NC40) of the amorphous phase in the polishing layer as measured by pulse NMR at 40° C. is 1.5-2.5.

2. The polishing pad according to claim 1,
wherein a numerical value that is obtained from Expression (1) below in which content proportions by weight of the amorphous phase and a crystalline phase in the polishing layer as measured by pulse NMR at 40° C. and 80° C. are used:
$$\begin{matrix}[ Math . 1 ] & \\ \frac{\begin{matrix}Content proportion by weight of amorphous \\ phase measured at 80 ° C . ( NC 80 )\end{matrix}}{\begin{matrix}Content proportion by weight of amorphous \\ phase measured at 40 ° C . ( NC 40 )\end{matrix}} - \frac{\begin{matrix}Content proportion by weight of crystalline \\ phase measured at 80 ° C . ( CC 80 )\end{matrix}}{\begin{matrix}Content proportion by weight of crystalline \\ phase measured at 40 ° C ( CC 40 )\end{matrix}} & Expression ( 1 )\end{matrix}$$
is 1.20-1.50.

3. The polishing pad according to claim 1,
wherein the NC40 is 10-20 weight %.

4. The polishing pad according to claim 1,
wherein the NC80 is 25-35 weight %.

5. The polishing pad according to claim 1,
wherein the polishing layer contains a polypropylene glycol and a polyether polycarbonate diol.

6. The polishing pad according to claim 5,
wherein a proportion of the polyether polycarbonate diol with respect to a total of the polypropylene glycol and the polyether polycarbonate diol is less than 80%.

7. A polishing pad comprising:
a polishing layer composed of a polyurethane resin foam derived an isocyanate-terminated prepolymer and from a curing agent,
wherein a numerical value that is obtained from Expression (2) below in which content proportions by weight of an amorphous phase and a crystalline phase in the polishing layer as measured by pulse NMR at 40° C. and 80° C. are used:
$$\begin{matrix}[ Math . 2 ] & \\ \frac{\begin{matrix}Content proportion by weight of amorphous \\ phase measured at 80 ° C . ( NC 80 )\end{matrix}}{\begin{matrix}Content proportion by weight of crystalline \\ phase measured at 40 ° C . ( CC 40 )\end{matrix}} - \frac{\begin{matrix}Content proportion by weight of amorphous \\ phase measured at 80 ° C . ( NC 80 )\end{matrix}}{\begin{matrix}Content proportion by weight of crystalline \\ phase measured at 40 ° C . ( CC 40 )\end{matrix}} & Expression ( 2 )\end{matrix}$$
is 0.70-1.30.

8. The polishing pad according to claim 7,
wherein a difference between a maximum value and a minimum value of tan δ as obtained by measuring the polishing layer by a dynamic mechanical analysis at 40° C.-80° C. is 0.030 or less.

9. The polishing pad according to claim 7,
wherein the NC40 is 10-20 weight %.

10. The polishing pad according to claim 7,
wherein the NC80 is 25-35 weight %.

11. The polishing pad according to claim 7,
wherein the polishing layer contains a polypropylene glycol and a polyether polycarbonate diol.

12. The polishing pad according to claim 11,
wherein a proportion of the polyether polycarbonate diol with respect to a total of the polypropylene glycol and the polyether polycarbonate diol is less than 80%.

13. A polishing pad comprising:
a polishing layer composed of a polyurethane resin foam derived from an isocyanate-terminated prepolymer and a curing agent,
wherein the isocyanate-terminated prepolymer includes a polyisocyanate compound-derived configuration unit and a high-molecular-weight polyol-derived configuration unit,
the high-molecular-weight polyol-derived configuration unit is composed of at least a polypropylene glycol configuration unit and a polyether polycarbonate diol configuration unit, and
there is less than 80 weight % of the polypropylene glycol configuration unit with respect to the high-molecular-weight polyol-derived configuration unit.

14. The polishing pad according to claim 13,
wherein there is 30-70 weight % of the polypropylene glycol configuration unit with respect to the high-molecular-weight polyol-derived configuration unit.

15. The polishing pad according to claim 13,
wherein the polyether polycarbonate diol configuration unit is derived from a polyether polycarbonate diol having a number-average molecular weight of 600-2500.

16. A method for manufacturing a polishing pad having a polishing layer composed of a polyurethane resin foam, the method comprising:
a step of reacting a polyisocyanate compound and a high-molecular-weight polyol containing at least a polypropylene glycol and a polyether polycarbonate diol to obtain an isocyanate-terminated prepolymer,
a step of reacting the isocyanate-terminated prepolymer and a curing agent to obtain the polyurethane resin foam, and
a step of molding the polyurethane resin foam into a shape of the polishing layer,
wherein there is less than 80 weight % of the polypropylene glycol with respect to a total amount of the high-molecular-weight polyol.
